(19) United States
(12) Patent Application Publication
(10) Pub. No.: US 2026/0040457 A1
(43) Pub. Date: Feb. 5, 2026

(54) WIRING CIRCUIT BOARD AND METHOD FOR PRODUCING WIRING CIRCUIT BOARD

(71) Applicant: NITTO DENKO CORPORATION, Osaka (JP)

(72) Inventors: Shusaku SHIBATA, Osaka (JP); Takahiro IKEDA, Osaka (JP); Teppei NIINO, Osaka (JP)

(73) Assignee: NITTO DENKO CORPORATION, Osaka (JP)

(21) Appl. No.: 18/994,946

(22) PCT Filed: Jun. 26, 2023
(86) PCT No.: PCT/JP2023/023620

§ 371 Date: Jan. 15, 2025

(30) Foreign Application Priority Data
Jul. 26, 2022 (JP) 2022-118683
Apr. 27, 2023 (JP) 2023-073352

(51) Int. Cl. H05K 1/18; H05K 3/30

(52) U.S. Cl. CPC H05K 1/181; H05K 3/301; H05K 2201/09236; H05K 2201/09263; H05K 2201/10121; H05K 2201/10424

(57) ABSTRACT

A method for producing a product board includes a first step, a second step, and a third step in order. In the first step, an intermediate board including a frame, a mounting portion, a first joint, and a second joint is prepared. The mounting portion is surrounded by the frame. The mounting portion is spaced apart from the frame. The first joint and the second joint connect the frame to the mounting portion. Each of the frame, the mounting portion, and the first joint in the intermediate board includes a base insulating layer and a wiring layer. The wiring layer is disposed on one surface of the base insulating layer in a thickness direction. In the second step, the intermediate board is inspected. In the third step, the second joint is removed.

### TECHNICAL FIELD

The present invention relates to a wiring circuit board and a method for producing a wiring circuit board.

### BACKGROUND ART

A wiring circuit board for mounting an imaging element is known (ref: for example, Patent Document 1 below). The wiring circuit board described in Patent Document 1 includes a frame, a mounting portion surrounded by the frame, and a supporting member which connects them. The wiring circuit board includes an insulating layer and a wiring layer disposed on one surface thereof.

After the wiring circuit board described in Patent Document 1 passes through an inspection step, an imaging element is mounted on a mounting portion. The inspection step includes, for example, an electrical conduction inspection of the wiring layer and an outer shape inspection of the insulating layer.

When the imaging element moves (vibrates), the frame moves (vibrates). Then, the mounting portion swings (sways) interlocked with the movement (vibration) of the frame. However, it is possible to correct the above-described swing (sway) of the mounting portion by the supporting member having low resilience. The above-described correction is referred to as a swing correction (sway correction).

### CITATION LIST

### Patent Document

Patent Document 1: Japanese Unexamined Patent Application Publication No. 2020-30306

### SUMMARY OF THE INVENTION

### Problem To Be Solved By The Invention

In the inspection step, when the frame moves, the mounting portion is not sufficiently interlocked with the movement of the frame caused by the supporting member having the low resilience, so that a posture of the mounting portion becomes unstable. Therefore, there is a problem that the handleability of the wiring circuit board in the inspection step is low.

The present invention provides a method for producing a wiring circuit board capable of producing a wiring circuit board capable of correcting a swing, while having excellent handleability in a second step, and the wiring circuit board.

### Means For Solving The Problem

The present invention [1] includes a method for producing a wiring circuit board including a first step of preparing a wiring circuit board including a frame, a mounting portion surrounded by the frame and spaced apart from the frame, and a first joint and a second joint connecting the frame to the mounting portion, and the wiring circuit board having each of the frame, the mounting portion, and the first joint including an insulating layer and a wiring layer disposed on one surface of the insulating layer in a thickness direction; a second step of inspecting the wiring circuit board; and a third step of removing the second joint in order.

According to this production method, since in the second step, the wiring circuit board includes the second joint, even when the frame is moved, the mounting portion is supported by the frame by the first joint and the second joint. Therefore, in the second step, it is possible to stabilize a posture of the mounting portion. As a result, the wiring circuit board in the second step has excellent handleability.

In the third step, the second joint is removed. Therefore, the mounting portion is supported by the frame by the first joint. Therefore, it is possible to reliably correct the swing of the mounting portion.

The present invention [2] includes the method for producing a wiring circuit board described in [1], wherein the mounting portion has a generally rectangular shape, and has a side at an outer peripheral edge of the mounting portion; the frame has a generally rectangular frame shape, and has a facing side facing the side and a non-facing side adjacent to the facing side and not facing the side; the first joint connects the side to the non-facing side; and the second joint connects the side to the facing side.

The first joint connects the side to the non-facing side, and the second joint connects the side to the facing side. Therefore, it is possible to make the first joint longer than the second joint. As a result, it is possible to improve the low resilience of the long first joint. On the other hand, it is possible to improve the rigidity of the short second joint.

The present invention [3] includes the method for producing a wiring circuit board described in [2], wherein the side includes a first side and a second side along the first side; at least each of the two first joints and the second joints is provided in the wiring circuit board in the first step; each of the two first joints is connected to each of the first side and the second side; and each of the two second joints is connected to each of the first side and the second side.

In this production method, in the wiring circuit board in the first step, each of the two first joints is connected to each of the first side and the second side, and each of the two second joints is connected to each of the first side and the second side. Therefore, in the second step, it is possible to further more stabilize the posture of the mounting portion in a direction in which the first side and the second side face.

The present invention [4] includes the method for producing a wiring circuit board described in any one of [1] to [3], wherein in the first step, the wiring circuit board further including a third joint connecting the frame to the first joint is prepared, and in the third step, the third joint is further removed.

In this production method, since in the first step, the wiring circuit board including the third joint which supports the first joint is prepared, it is possible to increase the rigidity of the first joint in the second step.

Further, in this production method, since in the third step, the third joint is removed, the mounting portion is supported by the first joint. Therefore, it is possible to reliably correct the swing of the mounting portion.

The present invention [5] includes the method for producing a wiring circuit board described in any one of [1] to [4], wherein the second joint includes the insulating layer.

The present invention [6] includes the method for producing a wiring circuit board described in [5], wherein the insulating layer in the second joint includes a base insulating layer and/or a cover insulating layer.

The present invention [7] includes the method for producing a wiring circuit board described in [6], wherein the second joint further includes the wiring layer.

The second joint includes the wiring layer in addition to the insulating layer. Therefore, in the second joint, the wiring layer can reinforce the insulating layer.

The present invention [8] includes the method for producing a wiring circuit board described in any one of [1] to [7], wherein each of the frame and the mounting portion further includes a metal supporting layer disposed on the other surface of the insulating layer in the thickness direction.

Since each of the frame and the mounting portion includes the metal supporting layer, it is possible to improve the rigidity.

The present invention [9] includes the method for producing a wiring circuit board described in [8], wherein the second joint includes the metal supporting layer.

Since the second joint includes the metal supporting layer, it is possible to improve the rigidity. Therefore, the mounting portion in the second step has the excellent handleability.

The present invention [10] includes the method for producing a wiring circuit board described in any one of [1] to [9], wherein the wiring layer in the first joint has a plurality of joint wirings spaced apart from each other, and the insulating layer in the first joint has a slit disposed between the plurality of joint wirings.

Since the first joint has the slit, it is possible to improve the low resilience of the first joint. Therefore, in the wiring circuit board, by removing the second joint, it is possible to further more reliably correct the swing of the mounting portion.

The present invention [11] includes the method for producing a wiring circuit board described in [10], wherein the slit extends along the plurality of joint wirings, and the first joint has a sub-joint dividing the slit in a direction in which the slit extends, and connecting the plurality of joint wirings.

In the wiring circuit board, it is possible to suppress a reduction in the rigidity of the first joint caused by the slit by the sub-joint. Therefore, it is possible to improve the handleability of the wiring circuit board in the second step.

The present invention [12] includes the method for producing a wiring circuit board described in any one of [1] to [10], wherein the second joint is not overlapped with the first joint in a thickness direction.

Since the second joint is not overlapped with the first joint, a configuration of the wiring circuit board in the first step is simple. Therefore, it is possible to easily remove the second joint in the third step.

The present invention [13] includes the method for producing a wiring circuit board described in [1] or [2], wherein the second joint intersects the first joint.

The present invention [14] includes the method for producing a wiring circuit board described in any one of [1] to [13] further including a fourth step of mounting an imaging element on the mounting portion after the first step and before the third step.

In this method, it is possible to stabilize the posture of the mounting portion in the fourth step before the third step of removing the second joint. Therefore, it is possible to reliably mount the imaging element on the mounting portion.

The present invention [15] includes the method for producing a wiring circuit board described in [14], wherein the fourth step is carried out after the second step.

In this method, in the second step, in a case where an intermediate board is defective by inspecting the intermediate board, even when the intermediate board is discarded, in the fourth step, it is possible to separately mount the above-described imaging element on another good intermediate board.

The present invention [16] includes a wiring circuit board including a frame, a mounting portion surrounded by the frame and spaced apart from the frame, and a first joint and a second joint connecting the frame to the mounting portion, wherein the mounting portion has a generally rectangular shape, and has a side at an outer peripheral edge of the mounting portion; the frame has a generally rectangular frame shape, and has a facing side facing the side and a non-facing side adjacent to the facing side and not facing the side: the first joint connects the side to the non-facing side: and the second joint connects the side to the facing side.

In this wiring circuit board, the first joint connects the side to the non-facing side, and the second joint connects the side to the facing side. Therefore, it is possible to make the first joint longer than the second joint. Therefore, it is possible to improve the rigidity of the short second joint. As a result, the wiring circuit board has the excellent handleability. On the other hand, it is possible to improve the low resilience of the long first joint. Therefore, when the second joint is removed, it is possible to reliably correct the swing of the mounting portion.

The present invention [17] includes the wiring circuit board described in [16], wherein each of the mounting portion and the first joint includes an insulating layer and a wiring layer disposed on one surface of the insulating layer in a thickness direction, and the second joint includes the insulating layer.

The present invention [18] includes the wiring circuit board described in [17], wherein the second joint further includes the wiring layer.

The second joint includes the wiring layer in addition to the insulating layer. Therefore, in the second joint, the wiring layer can reinforce the insulating layer.

The present invention [19] includes the wiring circuit board described in any one of [16] to [19], wherein each of the frame and the mounting portion further includes a metal supporting layer disposed on the other surface of the insulating layer in a thickness direction.

Since each of the frame and the mounting portion includes the metal supporting layer, it is possible to improve the rigidity.

The present invention [20] includes the wiring circuit board described in [16] or [17], wherein the insulating layer in the second joint includes a base insulating layer and/or a cover insulating layer.

The present invention [21] includes the wiring circuit board described in any one of [16] to [20], wherein the wiring layer in the first joint has a plurality of joint wirings spaced apart from each other, and the insulating layer in the first joint has a slit disposed between the plurality of joint wirings.

Since the first joint has the slit, it is possible to improve the low resilience of the first joint. Therefore, in the wiring circuit board after the third step, it is possible to further more reliably correct the swing of the mounting portion.

The present invention [22] includes the wiring circuit board described in [21], wherein the slit extends along the plurality of joint wirings, and the first joint has a sub-joint dividing the slit in a direction in which the slit extends, and connecting the plurality of joint wirings.

In the second step, it is possible to suppress a reduction of the rigidity of the first joint caused by the slit by the sub-joint. Therefore, it is possible to suppress an excessive deformation of the first joint.

The present invention [23] includes the wiring circuit board described in any one of [16] to [22] further including a third joint connecting the frame to the first joint.

Since the wiring circuit board includes the third joint, it is possible to increase the rigidity of the first joint.

### BRIEF DESCRIPTION OF THE DRAWINGS

FIG. 1 shows a plan view of an intermediate board prepared in a first step of one embodiment of a method for producing a wiring circuit board of the present invention.

FIG. 2 shows a plan view of a product board produced in a third step of one embodiment of a method for producing a wiring circuit board of the present invention.

FIG. 3 shows a partially enlarged view of the intermediate board shown in FIG. 1.

FIGS. 4 show process views of one embodiment of a method for producing a wiring circuit board of the present invention:

FIG. 4A illustrating a first step, and a cross-sectional view along an A-A line of FIG. 3,

FIG. 4B illustrating a fourth step, and

FIG. 4C illustrating a third step.

FIGS. 5 show preparation process views of the intermediate board shown in FIG. 4A:

FIG. 5A illustrating a step of forming a base insulating layer,

FIG. 5B illustrating a step of forming a wiring layer, and

FIG. 5C illustrating a step of forming a cover insulating layer.

FIG. 6 shows a cross-sectional view of a first modified example.

FIG. 7 shows a cross-sectional view of a second modified example.

FIG. 8 shows a cross-sectional view of a third modified example.

FIG. 9 shows a plan view of a fourth modified example.

FIG. 10 shows a plan view of a fifth modified example.

FIG. 11 shows a plan view of a sixth modified example.

FIG. 12 shows a plan view of a seventh modified example.

FIG. 13 shows a plan view of an eighth modified example.

FIG. 14 shows a plan view of a ninth modified example.

FIG. 15 shows a cross-sectional view along an A-A line of FIG. 14.

FIG. 16 shows a cross-sectional view of an intermediate board of a tenth modified example.

FIG. 17 shows a cross-sectional view of an intermediate board of an eleventh modified example.

FIG. 18 shows an enlarged plan view of an intermediate board of a twelfth modified example.

FIG. 19 shows an enlarged plan view of an intermediate board of a thirteenth modified example.

FIGS. 20 show process views of a fourteenth modified example:

FIG. 20A illustrating a first step.

FIG. 20B illustrating a third step, and

FIG. 20C illustrating a fourth step.

### DESCRIPTION OF EMBODIMENTS

### 1. One Embodiment of Method for Producing Wiring Circuit Board

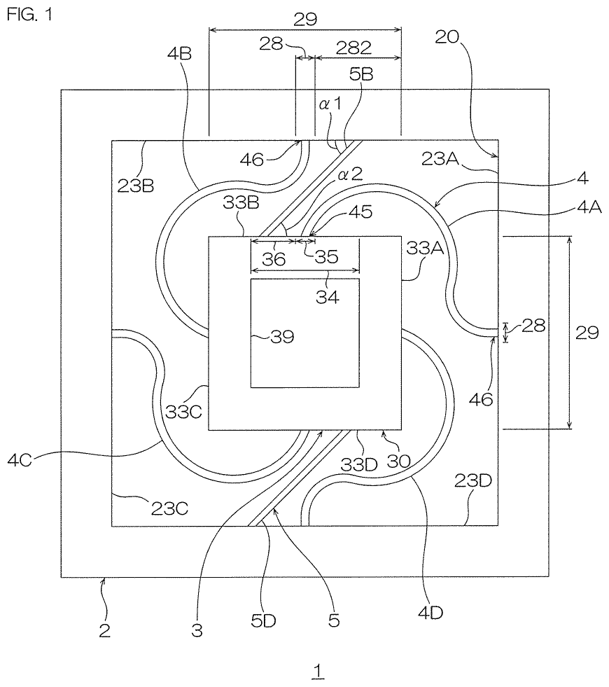

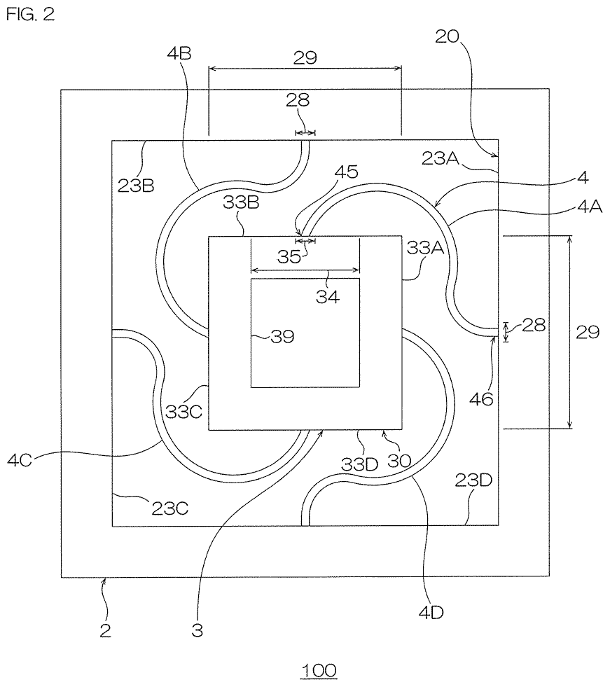

One embodiment of a method for producing a wiring circuit board of the present invention is described with reference to FIGS. 1 to 5C. In FIG. 2, in order to clearly show a shape and arrangement of a frame 2 and a mounting portion 3 (described later), an imaging element 105 and an external board 106 (described later) are omitted.

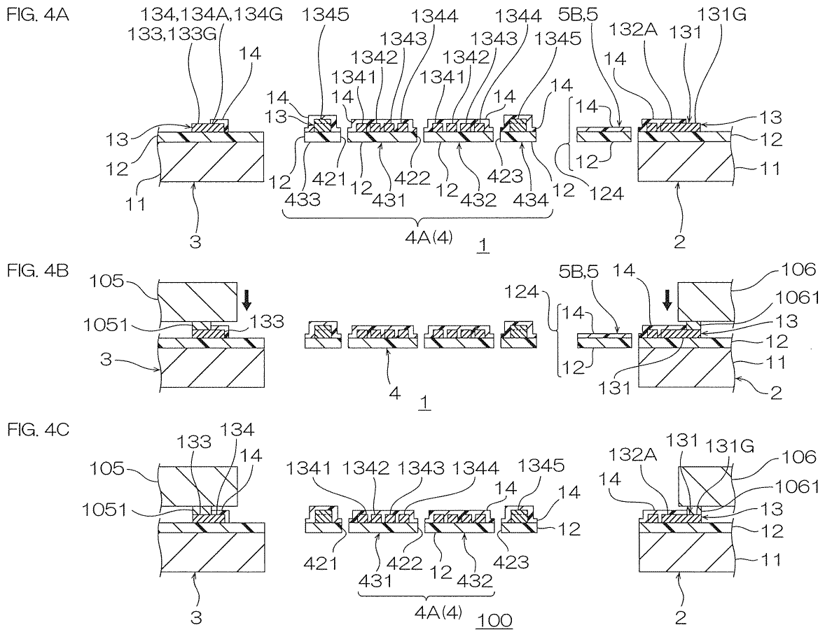

This production method includes a first step (ref: FIG. 1 and FIG. 4A), a second step, a fourth step (ref: FIG. 4B), and a third step (ref: FIG. 2 and FIG. 4C) in order. The first step, the second step, the fourth step, and the third step are carried out in order. Hereinafter, the first step, the second step, the fourth step, and the third step are described in order.

### 1.1 First Step

As shown in FIG. 1, in the first step, an intermediate board 1 as one example of a wiring circuit board is prepared. The intermediate board 1 is different from a product board 100 to be described later (ref: FIG. 2). That is, the intermediate board 1 includes a second joint 5 to be described later which is not provided in the product board 100. The intermediate board 1 is an intermediate component for producing the product board 100 (ref: FIG. 2).

The intermediate board 1 has a sheet shape. The intermediate board 1 has a thickness. The intermediate board 1 extends in a plane direction. The plane direction is orthogonal to a thickness direction. The intermediate board 1 includes the frame 2, the mounting portion 3, a first joint 4, and the second joint 5.

### 1.1.1 Frame 2

In the present embodiment, the frame 2 has a generally rectangular frame shape. The frame 2 includes an inner peripheral edge 20. In the present embodiment, the frame 2 has four sides 23A, 23B, 23C, and 23D at the inner peripheral edge 20. The four sides 23A, 23B, 23C, and 23D are disposed in order counterclockwise when viewed from the top. The side 23A and the side 23C face each other. The side 23B connects one end portion of the side 23A to one end portion of the side 23C. The side 23D connects the other end portion of the side 23A to the other end portion of the side 23C. The side 23B and the side 23D face each other.

As shown in FIG. 4A, the frame 2 includes a metal supporting layer 11, a base insulating layer 12, a wiring layer 13, and a cover insulating layer 14.

### 1.1.1.1 Metal Supporting Layer 11 in Frame 2

In the frame 2, the metal supporting layer 11 extends in the plane direction. The metal supporting layer 11 forms the other surface of the frame 2 in the thickness direction.

Examples of a material for the metal supporting layer 11 in the frame 2 include rigid materials. Examples of the rigid material include stainless steel, 42-alloy, aluminum, copper-beryllium, phosphor bronze, copper, silver, nickel, chromium, titanium, tantalum, platinum, gold, and copper alloys. As the rigid material, from the viewpoint of ensuring the strength of the frame 2, preferably, stainless steel and copper alloys are used. A thickness of the metal supporting layer 11 in the frame 2 is, for example, 30 μm or more, preferably 100 μm or more, and for example, 10,000 μm or less, preferably 1,000 μm or less.

### 1.1.2.2 Base Insulating Layer 12 in Frame 2

In the frame 2, the base insulating layer 12 is disposed on one surface of the metal supporting layer 11 in the thickness direction. In other words, in the frame 2, the metal supporting layer 11 is disposed on the other surface of the base insulating layer 12 in the thickness direction. The base insulating layer 12 is in contact with one surface of the metal supporting layer 11.

Examples of the material for the base insulating layer 12 in the frame 2 include resins, and preferably, a polyimide resin is used. The thickness of the base insulating layer 12 in the frame 2 is, for example, 1 μm or more, preferably 5 μm or more, and for example, below 20 μm, preferably 15 μm or less.

### 1.1.1.3 Wiring Layer 13 in Frame 2

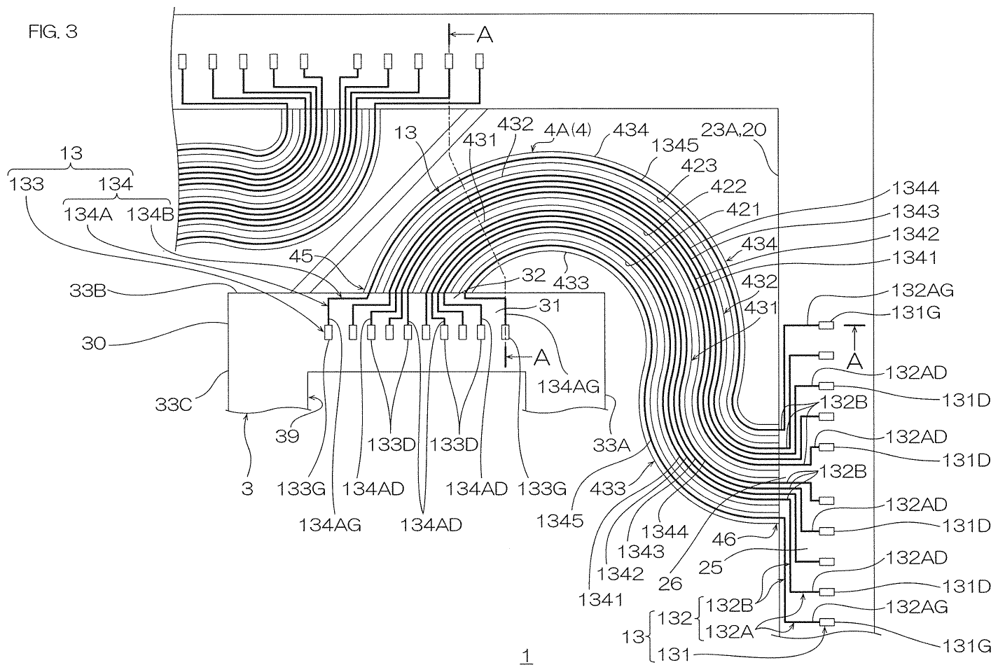

In the frame 2, the wiring layer 13 is disposed on one surface of the base insulating layer 12 in the thickness direction. The wiring layer 13 is in contact with one surface of the base insulating layer 12. As shown in FIG. 3, the wiring layer 13 includes a plurality of frame terminals 131 and a plurality of frame wirings 132.

### 1.1.1.4 Frame Terminal 131

The plurality of frame terminals 131 are provided corresponding to each of the four sides 23A, 23B (ref: FIG. 1), 23C (ref: FIGS. 1), and 23D (ref: FIG. 1). The plurality of frame terminals 131 corresponding to the side 23A are spaced apart from each other along the side 23A. Preferably, the plurality of frame terminals 131 are equally spaced apart from each other along the side 23A. The plurality of frame terminals 131 corresponding to the side 23A include a plurality of frame ground terminals 131G and a plurality of frame differential terminals 131D. Although not shown, the plurality of frame terminals 131 corresponding to each of the sides 23B (ref: FIG. 1), 23C (ref: FIGS. 1), and 23D (ref: FIG. 1) have the same configuration as the plurality of frame terminals 131 corresponding to the side 23A.

### 1.1.1.5 Frame Wiring 132

The plurality of frame wirings 132 are electrically connected to the plurality of frame terminals 131. In the present embodiment, the plurality of frame wirings 132 corresponding to the side 23A extend from each of the plurality of frame terminals 131 corresponding to the side 23A, bend, and converge to each other to thereafter reach the inner peripheral edge 20. Specifically, each of the plurality of frame wirings 132 includes a frame extending line 132A and a frame converging line 132B.

The frame extending line 132A corresponding to the side 23A extends from each of the plurality of frame terminals 131 corresponding to the side 23A toward the side 23A. The plurality of frame extending lines 132A corresponding to the side 23A are provided corresponding to the plurality of frame terminals 131 corresponding to the side 23A.

The plurality of frame extending lines 132A are spaced apart from each other in a direction along the side 23A. Each of the plurality of frame extending lines 132A extends in the direction intersecting the side 23A.

The frame extending line 132A includes a plurality of frame ground extending lines 132AG and a plurality of frame differential extending lines 132AD. Each of the plurality of frame ground extending lines 132AG extends from each of the plurality of frame ground terminals 131G. Each of the plurality of frame differential extending lines 132AD extends from each of the plurality of frame differential terminals 131D.

In the frame 2, a region where the plurality of frame extending lines 132A are provided is referred to as a third portion 25.

The frame extending line 132A corresponding to each of the sides 23B (ref: FIG. 1), 23C (ref: FIGS. 1), and 23D (ref: FIG. 1) has the same configuration as the frame extending line 132A corresponding to the side 23A described above.

The plurality of frame converging lines 132B corresponding to the side 23A are provided corresponding to the plurality of frame extending lines 132A corresponding to the side 23A. The plurality of frame converging lines 132B converge to each other, and go toward the vicinity of a second connecting portion 46 (described later) of a first joint 4A in the frame 2. Each of the plurality of frame converging lines 132B starts from one end edges of the plurality of frame extending lines 132A, and finishes at a site which is overlapped with the side 23A in the thickness direction. One end edge is an end edge at the opposite side of the frame terminal 131 in the frame extending line 132A. The starting point of the frame converging line 132B is a first bending point in the frame wiring 132. The frame converging line 132B is bent in a region facing the second connecting portion 46 of the first joint 4A. The above-described bending in the frame converging line 132B is a second bending point in the frame wiring 132. The second bending point of the frame wiring 132 is spaced apart from the first bending point of the frame wiring 132 in the direction along the side 23A. The second bending point may not face the corresponding frame terminal 131, while facing the first joint 4A in the direction orthogonal to the side 23A. The wiring density of the plurality of frame converging lines 132B is higher than the wiring density of the frame extending line 132A described above. The plurality of frame converging lines 132B may have equally spaced portions spaced apart from each other. In the present embodiment, each of the plurality of frame converging lines 132B bas a generally L-shape.

In the frame 2, the region where the frame converging line 132B is provided is referred to as a fourth portion 26. The fourth portion 26 is disposed between an inner peripheral edge 20 (the side 23A) and the above-described third portion 25. The side 23A, the fourth portion 26, and the third portion 25 are disposed in order. The wiring density of the frame converging line 132B in the fourth portion 26 is higher than the wiring density of the frame extending line 132A in the third portion 25.

The frame converging line 132B corresponding to each of the sides 23B (ref: FIG. 1), 23C (ref: FIGS. 1), and 23D (ref: FIG. 1) has the same configuration as the frame converging line 132B corresponding to the side 23A described above.

Examples of the material for the wiring layer 13 in the frame 2 include conductors. As the conductor, preferably, copper is used.

The thickness of the wiring layer 13 in the frame 2 is, for example, 1 μm or more, preferably 5 μm or more, and for example, 50 μm or less, preferably 35 μm or less.

### 1.1.1.6 Cover Insulating Layer 14 in Frame 2

As shown in FIG. 4A, in the frame 2, the cover insulating layer 14 is disposed on one surface of the base insulating layer 12 in the thickness direction. The cover insulating layer 14 covers the frame wiring 132 (the frame extending line 132A and the frame converging line 132B) as a portion of the wiring layer 13. The cover insulating layer 14 exposes the frame terminal 131 (the frame ground terminal 131G and the frame differential terminal 131D) as a remaining portion of the wiring layer 13.

Examples of the material for the cover insulating layer 14 include resins, and preferably, a polyimide resin is used. The thickness of the cover insulating layer 14 in the frame 2 is, for example, 1 μm or more, preferably 5 μm or more, and for example, below 20 μm, preferably 15 μm or less.

### 1.1.1.7 Dimension of Frame 2

An external dimension of the frame 2 is not limited. As shown in FIG. 1, each of an interval between the side 23A and the side 23C, and the interval between the side 23B and the side 23D is, for example, 5 mm or more, preferably 8 mm or more, and for example, 50 mm or less, preferably 30 mm or less. A length of each of the sides 23A, 23B, 23C, and 23D is, for example, 5 mm or more, preferably 8 mm or more, and for example, 50 mm or less, preferably 30 mm or less. A width of the frame 2 is, for example, 0.1 mm or more, preferably 0.3 mm or more, and for example, 50 mm or less, preferably 30 mm or less. The width of the frame 2 is the length between the inner peripheral edge 20 and the outer peripheral edge.

As shown in FIG. 3, the width of each of the plurality of frame terminals 131 is, for example, 10 μm or more, preferably 30 μm or more, and for example, 3000 μm or less, preferably 1000 μm or less.

A pitch of the plurality of frame terminals 131 is, for example, 30 μm or more, preferably 50 μm or more, and for example, 2000 μm or less, preferably 1000 μm or less. The pitch is the interval of each of the end edges of the frame terminals 131 adjacent to each other. Each of the two end edges is one end edge in the direction along the side 23A. The definition of the pitch is hereinafter the same.

In contrast, in the present embodiment, the pitch at the equally spaced portions of the plurality of frame converging lines 132B is smaller than the pitch of the plurality of frame extending lines 132A. The pitch at the equally spaced portions of the plurality of frame converging lines 132B is, for example, 1500 μm or less, preferably 1000 μm or less, more preferably 800 μm or less, and for example, 10 μm or more. A ratio of the pitch of the equally spaced portions of the plurality of frame converging lines 132B to the pitch of the plurality of frame extending lines 132A is, for example, below 1, preferably 0.8 or less, more preferably 0.5 or less, and for example, 0.01 or more.

The width of the frame wiring 132 is, for example, 1 μm or more, preferably 5 μm or more, and for example, 3000 μm or less, preferably 1000 μm or less.

### 1.1.2 Mounting Portion 3

As shown in FIG. 1, the mounting portion 3 is surrounded by the frame 2. The mounting portion 3 is spaced apart from the frame 2. In the present embodiment, the mounting portion 3 has a generally rectangular shape. Preferably, the mounting portion 3 has a generally rectangular outer shape, and specifically, has a generally rectangular frame shape. The mounting portion 3 includes an outer peripheral edge 30 and an inner peripheral edge 39. In the present embodiment, the mounting portion 3 includes four sides 33A, 33B, 33C, and 33D at the outer peripheral edge 30.

The four sides 33A, 33B, 33C, and 33D are disposed in order counterclockwise when viewed from the top. Each of the sides 33A, 33B, 33C, and 33D of the mounting portion 3 faces each of the sides 23A, 23B, 23C, and 23D of the frame 2.

In other words, the side 33B of the mounting portion 3 faces (is opposed to) the side 23B of the frame 2. In other words, the side 23B is a facing side with respect to the side 33B. The side 33B extends in the same direction as the side 23B.

The side 33B of the mounting portion 3 does not face (is not opposed to) the side 23A of the frame 2. In other words, the side 23A is a non-facing side with respect to the side 33B. The side 33B is adjacent to the side 33A. The side 33B extends in the direction intersecting the side 23A. Preferably, the side 33B extends in the direction orthogonal to the side 23A. In the present embodiment, the side 33B is one example of the first side.

The side 33C is along the same direction as the side 33A. The side 33B connects one end portion of the side 33A to one end portion of the side 33C.

The side 33D connects the other end portion of the side 33A to the other end portion of the side 33C. The side 33D is along the same direction as the side 33B. In other words, the side 33D is along the side 33B. The side 33D is one example of the second side.

As shown in FIG. 4A, the mounting portion 3 includes the metal supporting layer 11, the base insulating layer 12, the wiring layer 13, and the cover insulating layer 14.

### 1.1.2.1 Metal Supporting Layer 11 in Mounting Portion 3

In the mounting portion 3, the metal supporting layer 11 extends in the plane direction. The metal supporting layer 11 forms the other surface of the mounting portion 3 in the thickness direction. Each of the material and the thickness of the metal supporting layer 11 in the mounting portion 3 is the same as each of the material and the thickness of the metal supporting layer 11 in the frame 2.

### 1.1.2.2 Base Insulating Layer 12 in Mounting Portion 3

In the mounting portion 3, the base insulating layer 12 is disposed on one surface of the metal supporting layer 11 in the thickness direction. In other words, in the mounting portion 3, the metal supporting layer 11 is disposed on the other surface of the base insulating layer 12 in the thickness direction. The base insulating layer 12 is in contact with one surface of the metal supporting layer 11.

Each of the material and the thickness of the base insulating layer 12 in the mounting portion 3 is the same as each of the material and the thickness of the base insulating layer 12 in the frame 2.

### 1.1.2.3 Wiring Layer 13 in Mounting Portion 3

In the mounting portion 3, the wiring layer 13 is disposed on one surface of the base insulating layer 12 in the thickness direction. The wiring layer 13 is in contact with one surface of the base insulating layer 12. As shown in FIG. 3, the wiring layer 13 in the mounting portion 3 includes a plurality of terminals 133 and a plurality of wirings 134.

### 1.1.2.4 Terminal 133

As shown in FIG. 3, the plurality of terminals 133 are provided corresponding to each of the four sides 33A (ref: FIG. 1), 33B, 33C (ref: FIGS. 1), and 33D (ref: FIG. 1). Specifically, the plurality of terminals 133 corresponding to the side 33B are spaced apart from each other in the direction along the side 33B. Preferably, the plurality of terminals 133 are equally spaced apart from each other in the direction along the side 33B. The plurality of terminals 133 corresponding to the side 33B include a plurality of ground terminals 133G and a plurality of differential terminals 133D. Although not shown, the plurality of terminals 133 corresponding to each of the sides 33A (ref: FIG. 1), 33C (ref: FIGS. 1), and 33D (ref: FIG. 1) have the same configuration as the terminal 133 corresponding to the side 33B.

### 1.1.2.5 Wiring 134

The plurality of wirings 134 are electrically connected to the plurality of terminals 133. The plurality of wirings 134 are spaced apart from each other. In the present embodiment, the plurality of wirings 134 corresponding to the side 33B extend from each of the plurality of terminals 133 corresponding to the side 33B, and then, converge to each other to thereafter reach the outer peripheral edge 30. Specifically, each of the plurality of wirings 134 includes an extending line 134A and a converging line 134B.

The extending line 134A corresponding to the side 33B extends from each of the plurality of terminals 133 corresponding to the side 33B toward the side 33B. The plurality of extending lines 134A corresponding to the side 33B are provided corresponding to the plurality of terminals 133 corresponding to the side 33B.

The plurality of extending lines 134A are spaced apart from each other in the direction along the side 33B. Each of the plurality of extending lines 134A extends in the direction intersecting the side 33B. The extending line 134A includes a plurality of ground extending lines 134AG and a plurality of differential extending lines 134AD. Each of the plurality of ground extending lines 134AG extends from each of the plurality of ground terminals 133G. Each of the plurality of differential extending lines 134AD extends from each of the plurality of differential terminals 133D.

In the mounting portion 3, a region where the plurality of extending lines 134A are provided is referred to as a first portion 31. In other words, the mounting portion 3 includes the first portion 31. In other words, in the first portion 31, the plurality of wirings 134 extend from the plurality of terminals 133.

The extending line 134A corresponding to each of the sides 33A (ref: FIG. 1), 33C (ref: FIGS. 1), and 33D (ref: FIG. 1) has the same configuration as the extending line 134A corresponding to the above-described side 33B.

The plurality of converging lines 134B corresponding to the side 33B are provided corresponding to the extending line 134A corresponding to the side 33B. The plurality of converging lines 134B converge to each other, and go toward the vicinity of a connecting portion 45 (described later) of the first joint 4A in the mounting portion 3. Each of the plurality of converging lines 134B starts from one end edges of the plurality of extending lines 134A, and finishes at the site which is overlapped with the side 33B in the thickness direction. One end edge is the end edge at the opposite side of the terminal 133 in the extending line 134A. The starting point of the converging line 134B is the first bending point in the wiring 134. The converging line 134B is bent in a region facing the connecting portion 45 of the first joint 4A. The above-described bending in the converging line 134B is the second bending point in the wiring 134. The second bending point of the wiring 134 is spaced apart from the first bending point of the wiring 134 in the direction along the side 33B. The second bending point may not face the corresponding terminal 133, while facing the first joint 4A in the direction orthogonal to the side 33B. The wiring density of the plurality of converging lines 134B is higher than the wiring density of the extending line 134A described above. The plurality of converging lines 134B may have the equally spaced portions spaced apart from each other. In the present embodiment, each of the plurality of converging lines 134B has a generally L-shape.

In the mounting portion 3, the region where the converging line 134B is provided is referred to as a second portion 32. In other words, the mounting portion 3 has the second portion 32. The second portion 32 is disposed between the outer peripheral edge 30 (the side 33B) and the above-described first portion 31. The side 33B, the second portion 32, and the first portion 31 are disposed in order toward the inner peripheral edge 39. In the second portion 32, the plurality of wirings 134 converge. The wiring density of the converging line 134B in the second portion 32 is higher than the wiring density of the extending line 134A in the first portion 31.

### 1.1.2.6 Cover Insulating Layer 14 in Mounting Portion 3

As shown in FIG. 4A, in the mounting portion 3, the cover insulating layer 14 is disposed on one surface of the base insulating layer 12 in the thickness direction. The cover insulating layer 14 covers the wiring 134 (the extending line 134A and the converging line 134B) as a portion of the wiring layer 13. The cover insulating layer 14 exposes the terminal 133 as the remaining portion of the wiring layer 13.

### 1.1.2.7 Dimension of Mounting Portion 3

The external dimension of the mounting portion 3 is not limited. As shown in FIG. 1, each of the interval between the side 33A and the side 33C, and the interval between the side 33B and the side 33D is, for example, 3 mm or more, preferably 5 mm or more, and for example, 50 mm or less, preferably 30 mm or less. The length of each of the sides 33A, 33B, 33C, and 33D is, for example, 3 mm or more, preferably 5 mm or more, and for example, 50 mm or less, preferably 30 mm or less.

The width of the mounting portion 3 is, for example, 0.3 mm or more, preferably 0.5 mm or more, and for example, 30 mm or less, preferably 20 mm or less. The width of the mounting portion 3 is the length between the outer peripheral edge 30 and the inner peripheral edge 39.

As shown in FIG. 3, the width of each of the plurality of terminals 133 is the same as the width of each of the plurality of frame terminals 131 described above.

The pitch of the plurality of terminals 133 is, for example, 30 μm or more, preferably 50 μm or more, and for example, 2000 μm or less, preferably 1000 μm or less. The interval between the terminals 133 adjacent to each other is, for example, 10 μm or more, preferably 30 μm or more, more preferably 1500 μm or more, and for example, 800 μm or less.

The pitch of the plurality of extending lines 134A is preferably the same as the pitch of the plurality of terminals 133. The pitch at the equally spaced portion of the converging line 134B is smaller than the pitch of the plurality of extending lines 134A. The pitch at the equally spaced portion of the converging line 134B is, for example, 1500 μm or less, preferably 1000 μm or less, more preferably 800 μm or less, and for example, 10 μm or more. The ratio of the pitch of the equally spaced portion of the converging line 134B to the pitch of the plurality of extending lines 134A is, for example, below 1, preferably 0.8 or less, more preferably 0.5 or less, and for example, 0.01 or more.

The width of the wiring 134 is the same as the width of the above-described frame wiring 132.

### 1.1.3 First Joint 4

As shown in FIG. 1, the first joint 4 is disposed between the frame 2 and the mounting portion 3. The first joint 4 connects the frame 2 to the mounting portion 3. The plurality of first joints 4 are provided corresponding to the plurality of sides 33 in the mounting portion 3. In the present embodiment, each of the plurality of first joints 4A, 4B, 4C, and 4D corresponds to each of the plurality of sides 33B, 33C, 33D, and 33A in the mounting portion 3. Specifically, the first joint 4A connects the side 23A in the frame 2 to the side 33B (first side, non-facing side) in the mounting portion 3. The first joint 4B connects the side 23B in the frame 2 to the side 33C in the mounting portion 3. The first joint 4C connects the side 23C in the frame 2 to the side 33D (second side) in the mounting portion 3. The first joint 4D connects the side 23D in the frame 2 to the side 33A in the mounting portion 3.

In the following, detailed descriptions of the first joint 4A are provided. The first joints 4B, 4C, and 4D have the same configuration as the first joint 4A, and the detailed descriptions of these are omitted.

### 1.1.3.1 Shape of First Joint 4A

As shown in FIG. 3, in the present embodiment, the first joint 4A has a curved shape when viewed from the top. Preferably, the first joint 4A has only the curved shape without having a linear shape and/or a bent shape. Specifically, the first joint 4A has an S-shape or a hooked shape. When the first joint 4A has the curved shape, since the stress can be evenly relaxed without being locally concentrated, it is possible to improve the accuracy of a swing correction of the mounting portion 3.

### 1.1.3.2 Connection of First Joint 4 to Mounting Portion 3

The first joint 4A is connected to the second portion 32 in the mounting portion 3. That is, in the mounting portion 3, the first joint 4A is not connected to the first portion 31 where the plurality of extending lines 134A having the same pitch (relatively large pitch) as the plurality of terminals 133 are disposed, and is connected to the second portion 32 where the plurality of converging lines 134B having the smaller pitch than the plurality of terminals 133 are disposed.

The first joint 4A includes the connecting portion 45 connected to the second portion 32 described above. As shown in FIG. 1, for example, the connecting portion 45 is connected to a central region 34 of the side 33B in the mounting portion 3.

The central region 34 is a region including a central portion 35 in the side 33B. The central portion 35 is a central point in the side 33B and the vicinity thereof. The central region 34 has a length of a half of the length of the side 33B. The central region 34 preferably has the length of one third of the length of the side 33B, and more preferably has the length of one fourth of the length of the side 33B.

Preferably, the first joint 4A is connected to the central portion 35 of the side 33B.

The ratio (length of the connecting portion 45/length of the side 33B) of the length of the connecting portion 45 in the direction along the side 33B to the length of the side 33B is, for example, 0.3 or less, preferably 0.25 or less, more preferably 0.2 or less, and for example, 0.01 or more.

When the ratio of the length of the connecting portion 45 in the direction along the side 33B to the length of the side 33B is the above-described upper limit or less, it is possible to suppress the spread of the connecting portion 45 in the direction in which the side 33B extends. Therefore, it is possible to reliably reduce the rigidity of the first joint 4A.

### 1.1.3.3 Connection of First Joint 4 to Frame 2

As shown in FIG. 3, the first joint 4A is connected to the fourth portion 26 in the frame 2. That is, in the frame 2, the first joint 4A is not connected to the third portion 25 where the plurality of frame extending lines 132A having the same pitch (relatively large pitch) as the plurality of frame terminals 131 are disposed, and is connected to the fourth portion 26 where the plurality of converging lines 134B having the smaller pitch than the plurality of frame terminals 131 are disposed.

The first joint 4A includes the second connecting portion 46 connected to the fourth portion 26. As shown in FIG. 1, for example, the second connecting portion 46 is connected to a frame central region 29 of the side 23A in the frame 2.

The frame central region 29 is a region including a frame central portion 28 in the side 23A. The frame central portion 28 is the central point in the side 23A and the vicinity thereof. The frame central region 29 has the length of a half of the length of the side 23A. The frame central region 29 preferably has the length of one third of the length of the side 23A, and more preferably has the length of one fourth of the length of the side 23A.

Preferably, the first joint 4A is connected to the frame central portion 28 of the side 23A.

The ratio (length of the second connecting portion 46/length of the side 23A) of the length of the second connecting portion 46 in the direction along the side 23A to the length of the side 23A is, for example, 0.3 or less, preferably 0.25 or less, more preferably 0.2 or less, and for example, 0.01 or more.

When the ratio of the length of the second connecting portion 46 in the direction along the side 23A to the length of the side 23A is the above-described upper limit or less, it is possible to suppress the spread of the second connecting portion 46 in the direction in which the side 23A extends. Therefore, it is possible to reliably reduce the rigidity of the first joint 4A.

As shown in FIG. 4A, in the present embodiment, the first joint 4A includes a plurality of slits 421, 422, and 423, a plurality of wiring body portions 431 and 432, and ground wiring body portions 433 and 434.

### 1.1.3.4 Slits 421, 422, 423

Each of the plurality of slits 421, 422, and 423 is disposed in an intermediate portion of the first joint 4 in the direction intersecting the direction in which the first joint 4 extends (intersecting direction, preferably, orthogonal direction). The plurality of slits 421, 422, and 423 are spaced apart from each other in the intersecting direction. Each of the plurality of slits 421, 422, and 423 is disposed in the entire direction in which the first joint 4 extends in the first joint 4. The plurality of slits 421, 422, and 423 are disposed in order toward the intersecting direction. The plurality of slits 421, 422, and 423 partition the wiring body portion 431, the wiring body portion 432, the ground wiring body portion 433, and the ground wiring body portion 434. Each of the plurality of slits 421, 422, and 423 penetrates the base insulating layer 12 and the cover insulating layer 14 to be described later in the thickness direction.

### 1.1.3.5 Wiring Body Portions 431, 432

The wiring body portion 431 and the wiring body portion 432 are partitioned by the slits 421, 422, and 423. The wiring body portion 431 and the wiring body portion 432 are spaced apart from each other in the intersecting direction. The plurality of slits 421, 422, and 423 extend along the wiring body portions 431 and 432. Each of the wiring body portion 431 and the wiring body portion 432 includes four joint wirings 1341, 1342, 1343, and 1344, the base insulating layer 12, and the cover insulating layer 14. In other words, the first joint 4 includes the four joint wirings 1341, 1342, 1343, and 1344, the base insulating layer 12, and the cover insulating layer 14.

The joint wirings 1341, 1342, 1343, and 1344 are spaced apart from each other in the intersecting direction. The joint wirings 1341, 1342, 1343, and 1344 are disposed in order in the intersecting direction. The plurality of slits 421, 422, and 423 extend along the joint wirings 1341, 1342, 1343, and 1344. In the present embodiment, the joint wirings 1341, 1342, 1343, and 1344 can function as differential wirings. For example, the joint wiring 1341 and the joint wiring 1342 operate as differential pairs. The joint wiring 1343 and the joint wiring 1344 operate as differential pairs.

The one base insulating layer 12 is in contact with the other surfaces of the joint wirings 1341, 1342, 1343, and 1344 in the thickness direction in each of the wiring body portions 431 and 432.

The one cover insulating layer 14 collectively covers the joint wirings 1341, 1342, 1343, and 1344 in each of the wiring body portions 431 and 432. The cover insulating layer 14 is in contact with one surface and an outer-side surface of each of the joint wirings 1341, 1342, 1343, and 1344.

### 1.1.3.6 Ground Wiring Body Portions 433, 434

The ground wiring body portion 433 is disposed apart from the wiring body portion 431 via the slit 421. The ground wiring body portion 434 is disposed apart from the wiring body portion 432 via the slit 423. Each of the ground wiring body portions 433 and 434 includes the ground wiring 1345, the base insulating layer 12, and the cover insulating layer 14.

The one base insulating layer 12 is in contact with the lower surface of the ground wiring 1345 in the thickness direction in each of the ground wiring body portions 433 and 434. The ground wiring 1345 is thicker than the joint wirings 1341, 1342, 1343, and 1344.

The one cover insulating layer 14 covers the ground wiring 1345 in each of the ground wiring body portions 433 and 434. The cover insulating layer 14 is in contact with one surface in the thickness direction and the outer-side surface of the ground wiring 1345.

As shown in FIG. 3, the ground wiring 1345 is electrically connected to the frame ground terminal 131G in the frame 2. Specifically, the ground wiring 1345 is electrically connected to the metal supporting layer 11 in the frame 2 via the converging line 134B corresponding to the ground extending line 134AG, the ground extending line 134AG, and the frame ground terminal 131G. Thus, the ground wiring 1345 is grounded to the frame ground terminal 131G.

As shown in FIG. 4A, the first joint 4A does not include, for example, the metal supporting layer 11. The metal supporting layer 11 is a layer disposed on the other surface of the base insulating layer 12 in the thickness direction. Examples of the material for the metal supporting layer 11 include the above-described rigid materials.

The first joint 4A includes the base insulating layer 12, the wiring layer 13, and the cover insulating layer 14. Preferably, the first joint 4A includes only the base insulating layer 12, the wiring layer 13, and the cover insulating layer 14.

### 1.1.3.7 Base Insulating Layer 12 in First Joint 4A

In the first joint 4A, the base insulating layer 12 forms the other surface of the first joint 4A in the thickness direction. The base insulating layer 12 is exposed toward the other side in the thickness direction.

The base insulating layer 12 has the plurality of slits 421, 422, and 423 described above. The plurality of slits 421, 422, and 423 are disposed between the wiring body portions 431 and 432, between the wiring body portion 431 and the ground wiring body portion 433, and between the wiring body portion 432 and the ground wiring body portion 434.

### 1.1.3.8 Wiring Layer 13 in First Joint 4A

In the first joint 4A, the wiring layer 13 includes the above-described joint wirings 1341, 1342, 1343, and 1344 and the above-described two ground wirings 1345.

In the first joint 4A, the wiring layer 13 is disposed on one surface of the base insulating layer 12 in the thickness direction. The wiring layer 13 is in contact with one surface of the base insulating layer 12. The joint wirings 1341, 1342, 1343, and 1344 are spaced apart from each other in the intersecting direction (preferably, orthogonal direction) in the first joint 4A. As shown in FIG. 3, the joint wirings 1341, 1342, 1343, and 1344 are electrically connected to the plurality of wirings 134. Further, the joint wirings 1341, 1342, 1343, and 1344 are electrically connected to the plurality of frame wirings 132. That is, the plurality of joint wirings 1341, 1342, 1343, and 1344 electrically connect the plurality of frame wirings 132 in the frame 2 to the plurality of wirings 134 in the mounting portion 3.

### 1.1.3.9 Cover Insulating Layer 14 in First Joint 4A

As shown in FIG. 4A, in the first joint 4A, the cover insulating layer 14 forms one surface of the first joint 4A in the thickness direction. The cover insulating layer 14 is exposed toward one side in the thickness direction. The cover insulating layer 14 is disposed on one surface of the base insulating layer 12 in the thickness direction. The cover insulating layer 14 covers the plurality of joint wirings 1341, 1342, 1343, and 1344 and the ground wiring 1345.

The cover insulating layer 14 has the above-described plurality of slits 421, 422, and 423 together with the base insulating layer 12. Each of the plurality of slits 421, 422, and 423 penetrates the cover insulating layer 14 in the thickness direction. An inner-side surface partitioning each of the plurality of slits 421, 422, and 423 in the cover insulating layer 14 is flush with the inner-side surface partitioning each of the plurality of slits 421, 422, and 423 in the base insulating layer 12.

### 1.1.3.10 Dimension of First Joint 4A

The ratio of the thickness of the ground wiring 1345 to the thickness of the joint wirings 1341, 1342, 1343, and 1344 is, for example, 0.5 or more, preferably 0.8 or more, more preferably 1 or more, and for example, 10 or less. The thickness of the joint wirings 1341, 1342, 1343, and 1344 is the same as the thickness of the frame wiring 132. The thickness of the ground wiring 1345 is, for example, 3 μm or more, preferably 6 μm or more, and for example, 100 μm or less, preferably 50 μm or less.

The width of the joint wirings 1341, 1342, 1343, and 1344 and the width of the ground wiring 1345 are the same as the width of the frame wiring 132.

The plurality of first joints 4A, 4B, 4C, and 4D may have the same lengths or may have the different lengths. When the lengths of the plurality of first joints 4A, 4B, 4C, and 4D are different from each other, a difference in length between the longest first joint 4 and the shortest first joint 4 is, for example, 3 mm or less, preferably 2 mm or less, more preferably 1.5 mm or less. When the difference in length between the longest first joint 4 and the shortest first joint 4 is the above-descried upper limit or less, it is possible to improve the accuracy of the swing correction of the mounting portion 3.

The thickness of each of the plurality of wiring body portions 431 and 432 is, for example, 3 μm or more, preferably 5 μm or more, and for example, 100 μm or less, preferably 50 μm or less. The width of each of the plurality of wiring body portions 431 and 432 is, for example, 5 μm or more, preferably 10 μm or more, and for example, 500 μm or less, preferably 300 μm or less.

The thickness of each of the ground wiring body portions 433 and 434 is, for example, 3 μm or more, preferably 5 μm or more, and for example, 100 μm or less, preferably 50 μm or less. The width of each of the ground wiring body portions 433 and 434 is, for example, 5 μm or more, preferably 10 μm or more, and for example, 500 μm or less, preferably 300 μm or less.

The width of each of the slits 421, 422, and 423 is, for example, 5 μm or more, preferably 10 μm or more, and for example, 500 μm or less, preferably 300 μm or less.

### 1.1.4 Second Joint 5

As shown in FIG. 1, the second joint 5 is disposed between the frame 2 and the mounting portion 3. The second joint 5 connects the frame 2 to the mounting portion 3. The plurality of (two) second joints 5 are provided corresponding to the plurality of sides 33 in the mounting portion 3. In the present invention, each of two second joints 5B and 5D corresponds to each of the two sides 33B and 33D.

Specifically, the second joint 5B connects the side 23B in the frame 2 to the side 33B (first side) in the mounting portion 3. The second joint 5B is connected to the side 33B as the first side in the mounting portion 3. The side 33B is the facing side with respect to the side 23B.

Further, the second joint 5D connects the side 23D in the frame 2 to the side 33D in the mounting portion 3. In other words, the second joint 5D is connected to the side 33D as the second side in the mounting portion 3. The side 33D is the facing side with respect to the side 23D. In the present embodiment, the second joint 5D is disposed at the opposite side of the second joint 5B with respect to the mounting portion 3.

The two first joints 4B and 4C (or the first joints 4D and 4A) are disposed between the two second joints 5B and 5D in the direction along the periphery of the mounting portion 3. In other words, in the present embodiment, the one second joint 5B is located between the two first joints 4A and 4B in the direction along the periphery of the mounting portion 3. The one second joint 5D is located between the two first joints 4C and 4D in the direction along the periphery of the mounting portion 3. In the present embodiment, the first joint 4A, the second joint 5B, the first joint 4B, the first joint 4C, the second joint 5D, and the first joint 4D are disposed in order counterclockwise in the direction along the periphery of the mounting portion 3.

In the following, the detailed descriptions of the second joint 5B are provided. The second joint 5D has the same configuration as the second joint 5B, and the detailed descriptions thereof are omitted.

### 1.1.4.1 Shape of Second Joint 5B

As shown in FIG. 1, the second joint 5B has the linear shape when viewed from the top. Further, the second joint 5 may be inclined or may be orthogonal to each of the side 23B and the side 33B. When the second joint 5 is inclined to each of the side 23B and the side 33B, an acute angle al formed by the second joint 5 and the side 23B is, for example, 5 degrees or more, preferably 15 degrees or more, and for example, below 90 degrees. An acute angle α2 formed by the second joint 5 and the side 33B is, for example, 5 degrees or more, preferably 15 degrees or more, and for example, below 90 degrees.

Further, the second joint 5B crosses a line segment connecting the connecting portion 45 of the first joint 4A to the second connecting portion 46 of the first joint 4B.

The second joint 5B is not overlapped with the first joint 4A connected to the side 33B in the thickness direction. The second joint 5B is not overlapped with the first joint 4B connected to the side 23B in the thickness direction. That is, the second joint 5B is spaced apart from each of the first joint 4A and the first joint 4B when viewed from the top.

### 1.1.4.2 Connection of Second Joint 5 to Mounting Portion 3

In the present embodiment, the second joint 5B is connected to the central region 34 of the side 33B. Specifically, the second joint 5B is connected to a first position 36. The first position 36 is deviated from the central portion 35 toward the side 33C-side in the central region 34. The first position 36 is included in the central region 34.

### 1.1.4.3 Connection of Second Joint 5 to Frame 2

In the present embodiment, the second joint 5B is connected to the frame central region 29 at the side 23B. Specifically, the second joint 5B is connected to a fourth position 282. The fourth position 282 is deviated from the frame central portion 28 toward the side 23A-side in the frame central region 29. The fourth position 282 is included in the frame central region 29.

### 1.1.4.3 Layer Structure of Second Joint 5B

As shown in FIG. 4A, the second joint 5B includes the base insulating layer 12 and the cover insulating layer 14. In the present embodiment, the second joint 5 includes only the base insulating layer 12 and the cover insulating layer 14.

### 1.1.4.4 Base Insulating Layer 12 in Second Joint 5B

In the second joint 5B, the base insulating layer 12 forms the other surface of the second joint 5B in the thickness direction. The base insulating layer 12 is exposed toward the other side in the thickness direction. Each of the material and the thickness of the base insulating layer 12 in the second joint 5B is the same as each of the material and the thickness of the base insulating layer 12 in the frame 2.

### 1.1.4.5 Cover Insulating Layer 14 in Second Joint 5B

In the second joint 5B, the cover insulating layer 14 forms one surface of the second joint 5B in the thickness direction. The cover insulating layer 14 is exposed toward one side in the thickness direction. In the second joint 5B, the cover insulating layer 14 is disposed on one surface of the base insulating layer 12 in the thickness direction. The cover insulating layer 14 is in contact with one surface of the base insulating layer 12. Each of both side surfaces of the cover insulating layer 14 is, for example, flush with each of both side surfaces of the base insulating layer 12. Each of the material and the thickness of the cover insulating layer 14 in the second joint 5B is the same as each of the material and the thickness of the cover insulating layer 14 in the frame 2.

In the second joint 5B, the cover insulating layer 14 forms a joint insulator portion 124 together with the base insulating layer 12. The thickness of the joint insulator portion 124 is, for example, 5 μm or more, preferably 10 μm or more, and for example, 100 μm or less, preferably 50 μm or less.

### 1.1.4.6 Dimension of Second Joint 5B

As shown in FIG. 1, the length of the second joint 5B is, for example, 0.5 mm or more, preferably 1 mm or more, and for example, 20 mm or less, preferably 15 mm or less. The length of the second joint 5B is the length in which the second joint 5B extends.

The width of the second joint 5B is, for example, 100 μm or more, preferably 500 μm or more, and for example, 8000 μm or less, preferably 5000 μm or less. The width of the second joint 5B is the length in the direction orthogonal to the direction in which the second joint 5B extends. In the present embodiment, the width of the second joint 5B is the same in the direction in which the second joint 5B extends.

The ratio of the width of the second joint 5B to the width of each of the plurality of wiring body portions 431 and 432 is, for example, 1 or more, preferably 3 or more, and for example, 100 or less, preferably, 50 or less.

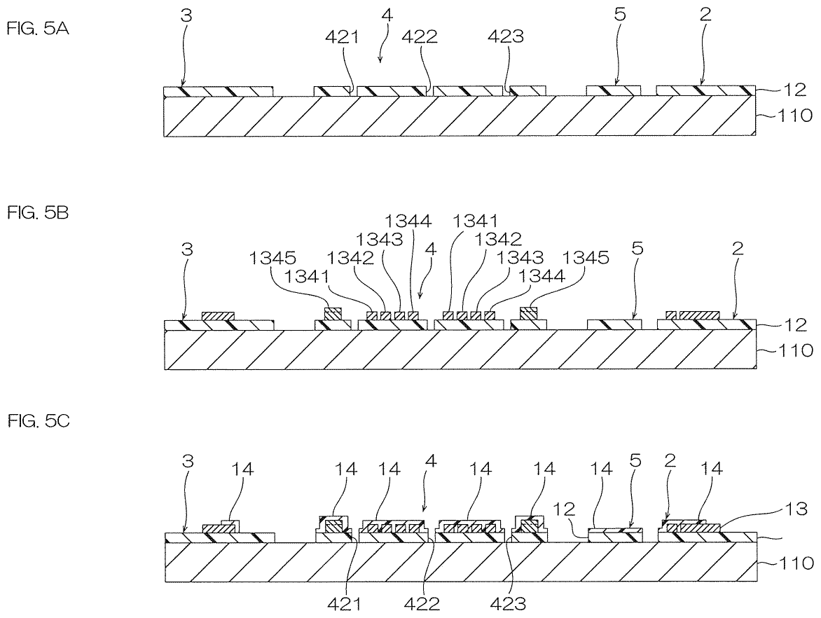

1.1.5 Method for Preparing Intermediate Board 1 A method for preparing the intermediate board 1 is described with reference to FIGS. 5A to 5C.

As shown in FIG. 5A, in this method, first, the base insulating layer 12 is formed on one surface of a metal supporting board 110 in the thickness direction.

The metal supporting board 110 is a metal board for forming the metal supporting layer 11. The metal supporting board 110 is made of the same material as the metal supporting layer 11, and has the same thickness as the metal supporting layer 11.

For example, a resin is applied to one surface of the metal supporting board 110, and the base insulating layer 12 having a pattern corresponding to the frame 2, the mounting portion 3, the first joint 4, and the second joint 5 is formed by photolithography. In this step, the base insulating layer 12 of the frame 2, the base insulating layer 12 of the mounting portion 3, the base insulating layer 12 of the first joint 4, and the base insulating layer 12 of the second joint 5 are formed simultaneously.

As shown in FIG. 5B, next, the wiring layer 13 is formed on one surface of the base insulating layer 12 in the thickness direction. For example, the wiring layer 13 is formed by a conductor pattern forming method. Examples of the conductor pattern forming method include additive methods and subtractive methods, and preferably, an additive method is used. In order to form the wiring layer 13 by the additive method, first, the wiring layer 13 of the frame 2, a portion of the wiring layer 13 of the mounting portion 3, and the wiring layer 13 of the first joint 4 are formed simultaneously. A portion of the wiring layer 13 of the mounting portion 3 is other-side portions (ref: phantom line) of the joint wirings 1341, 1342, 1343, and 1344, and the ground wiring 1345 in the thickness direction. Thereafter, a one-side portion (ref: phantom line) of the ground wiring 1345 in the thickness direction is laminated on the other-side portion of the ground wiring 1345.

As shown in FIG. 5C, the cover insulating layer 14 is formed on one surface of the base insulating layer 12 in the thickness direction.

For example, the resin is applied to one surfaces of the metal supporting board 110, the base insulating layer 12, and the wiring layer 13, and the cover insulating layer 14 having the pattern corresponding to the frame 2, the mounting portion 3, the first joint 4, and the second joint 5 is formed by the photolithography. In this step, the cover insulating layer 14 of the frame 2, the cover insulating layer 14 of the mounting portion 3, the cover insulating layer 14 of the first joint 4, and the cover insulating layer 14 of the second joint 5 are formed simultaneously.

Thereafter, as shown in FIG. 4A, an outer shape of the metal supporting board 110 is processed, thereby forming the metal supporting layer 11. Examples of the outer shape processing include etching, punching, and laser. As the outer shape processing, preferably, from the viewpoint of productivity, etching is used. The metal supporting board 110 between the frame 2 and the mounting portion 3 is removed by the outer shape processing of the metal supporting board 110. Thus, each of the first joint 4 and the second joint 5 does not include the metal supporting layer 11.

Thus, the intermediate board 1 is prepared.

### 1.2 Second Step

In the second step, the intermediate board 1 is inspected. The second step includes an electrical conduction inspection of the wiring layer 13 and an outer shape inspection of the metal supporting layer 11, the base insulating layer 12, and the cover insulating layer 14.

When the intermediate board 1 is inspected in the second step, the frame 2 is gripped by an operator or a conveyance device. Then, the intermediate board 1 is conveyed to an inspection device. In the inspection device, the frame 2 is placed on an inspection table (not shown). The frame 2 is in contact with the inspection table. After the inspection of the intermediate board 1, the intermediate board 1 is taken out from the inspection device. Thereafter, the intermediate board 1 is subjected to the next fourth step, while the frame 2 is gripped by the operator or the conveyance device.

### 1.3 Fourth Step

As shown in FIG. 4B, the fourth step is carried out after the second step. In other words, the fourth step is carried out after the first step and before the third step. In the fourth step, the frame 2 is in contact with a device (mounting device). In the fourth step, the imaging element 105 is mounted on the mounting portion 3. An electrode 1051 of the imaging element 105 is electrically connected to the plurality of terminals 133 in the mounting portion 3. The imaging element 105 may be mounted on the mounting portion 3 via a mounting board which is not shown.

In addition, the external board 106 is mounted on the frame 2. An electrode 1061 of the external board 106 is electrically connected to the plurality of frame terminals 131 in the frame 2.

By the fourth step, the intermediate board 1 on which the imaging element 105 is mounted is obtained. Specifically, the intermediate board 1 in which the imaging element 105 is mounted on the mounting portion 3, and the external board 106 is mounted on the frame 2 is obtained.

### 1.4 Third Step

As shown in FIGS. 2 and 4C, in the third step, the second joint 5 is removed. Examples of a method for removing the second joint 5 include cutting using a sheet cutter, etching, punching, and laser. As the method for removing the second joint 5, preferably, from the viewpoint of productivity, cutting, punching, and laser are used. Thus, the mounting portion 3 is supported by the frame 2 via only the first joint 4.

By the third step, the second joint 5 is removed from the intermediate board 1, thereby producing the product board 100. That is, the product board 100 does not include the second joint 5, and includes the frame 2, the mounting portion 3, and the first joint 4. In the product board 100, the imaging element 105 and the external board 106 are mounted.

### 2. Function and Effect of One Embodiment

According to this production method, as shown in FIGS. 1 and 4B, in the second step, the intermediate board 1 still includes the second joint 5. Then, even when the frame 2 is moved, the mounting portion 3 is supported by the frame 2 by the first joint 4 and the second joint 5. Therefore, in the second step, it is possible to stabilize a posture of the mounting portion 3. As a result, the intermediate board 1 in the second step has the excellent handleability.

As shown in FIG. 2 and FIG. 4C, in the third step, the second joint 5 is removed. Therefore, the mounting portion 3 is supported by the frame 2 only by the first joint 4. Therefore, it is possible to reliably correct the swing of the mounting portion 3 in the product board 100.

As shown in FIG. 1, the first joint 4A connects the side 33B to the side 23A which is the non-facing side with respect to the side 33B, and the second joint 5B connects the above-described side 33B to the side 23B which is the facing side with respect to the side 33B. Therefore, it is possible to make the first joint 4A longer than the second joint 5B. As a result, it is possible to improve the low resilience of the long first joint 4A. On the other hand, it is possible to improve the rigidity of the short second joint 5B.

In the intermediate board 1 in the first step, each of the two first joint 4A and the first joint 4C is connected to each of the side 33B as the first side and the side 33D as the second side. In the intermediate board 1 in the first step, each of the two second joint 5B and the second joint 5D is connected to each of the side 33B as the first side and the side 33D as the second side.

Therefore, in the second step, it is possible to further more stabilize the posture of the mounting portion 3 in the direction in which the side 33B and the side 33D face.

Since each of the frame 2 and the mounting portion 3 includes the metal supporting layer 11, it is possible to improve the rigidity.

Since the second joint 5 includes the metal supporting layer 11, it is possible to improve the rigidity. Therefore, the mounting portion 3 in the second step has the excellent handleability.

Since the second joint 5B is not overlapped with the first joints 4A and 4B, a configuration of the intermediate board 1 in the first step is simple. Therefore, it is possible to easily remove the second joint 5 in the third step.

As shown in FIG. 4A, the first joint 4A has the slits 421, 422, and 423. Therefore, it is possible to make the first joint 4A fragile, and it is possible to improve the low resilience of the first joint 4A. As a result, as shown in FIG. 4C, in the product board 100 after the third step, it is possible to further more reliably correct the swing of the mounting portion 3.

In this method, as shown in FIG. 4B, it is possible to stabilize the posture of the mounting portion 3 in the fourth step before the third step of removing the second joint 5. Therefore, it is possible to reliably mount the imaging element 105 on the mounting portion 3.

### 3. Modified Examples

In each modified example below, the same reference numerals are provided for members and steps corresponding to each of those in the above-described one embodiment, and their detailed description is omitted. Further, each modified example can achieve the same function and effect as that of one embodiment unless otherwise specified. Furthermore, one embodiment and each modified example can be appropriately used in combination.

### 3.1 First Modified Example

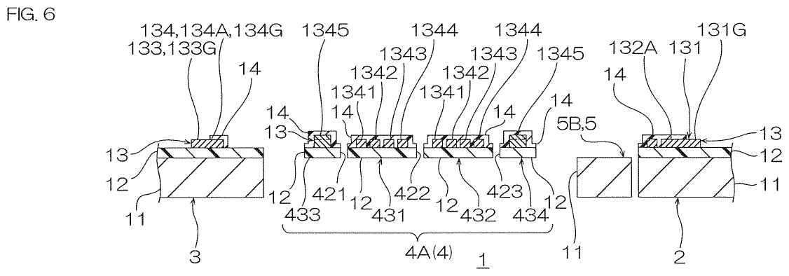

As shown in FIG. 6, the second joint 5 does not include the base insulating layer 12 and the cover insulating layer 14, and includes the metal supporting layer 11. In the first modified example, the second joint 5 includes only the metal supporting layer 11. The metal supporting layer 11 in the second joint 5 has the same configuration as the metal supporting layer 11 in the frame 2.

In the first modified example, since the second joint 5 includes the metal supporting layer 11, the second joint 5 has the excellent rigidity as compared with one embodiment in which the second joint 5 is formed of the joint insulator portion 124.

### 3.2 Second Modified Example

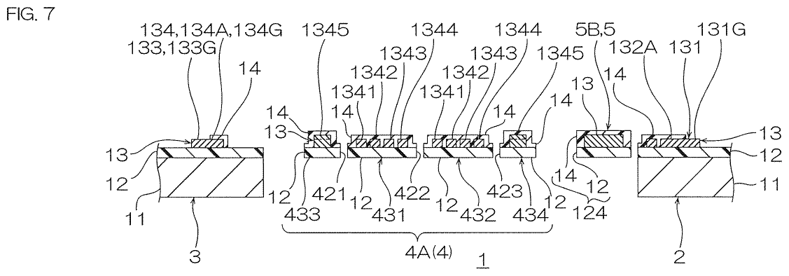

As shown in FIG. 7, the second joint 5 includes the base insulating layer 12, the wiring layer 13, and the cover insulating layer 14. That is, the second joint 5 of the second modified example further includes the wiring layer 13 in addition to the base insulating layer 12 and the cover insulating layer 14 in the second joint 5 of one embodiment shown in FIG. 4A.

In the second modified example, the wiring layer 13 in the second joint 5 has the same configuration as the wiring layer 13 in one embodiment. In the second modified example, the wiring layer 13 in the second joint 5, for example, does not have the function of conveying electricity. In the second modified example, the wiring layer 13 is a core material for the base insulating layer 12 and the cover insulating layer 14 (the joint insulator portion 124), and reinforces the joint insulator portion 124.

The width of the wiring layer 13 of the second joint 5 in the second modified example may be the same as or may be wider than the width of the joint wirings 1341, 1342, 1343, and 1344 in the first joint 4. When the width of the wiring layer 13 of the second joint 5 is wider than the width of the joint wirings 1341, 1342, 1343, and 1344, the ratio of the width of the wiring layer 13 of the second joint 5 to the width of the joint wirings 1341, 1342, 1343, and 1344 is, for example, 1.5 or more, preferably 2 or more, more preferably 3 or more, and for example, 50 or less.

### 3.2.1 Function and Effect of Second Modified Example

The second joint 5 includes the wiring layer 13 in addition to the base insulating layer 12. Therefore, in the second joint 5, the wiring layer 13 can reinforce the joint insulator portion 124 including the base insulating layer 12.

### 3.3 Third Modified Example

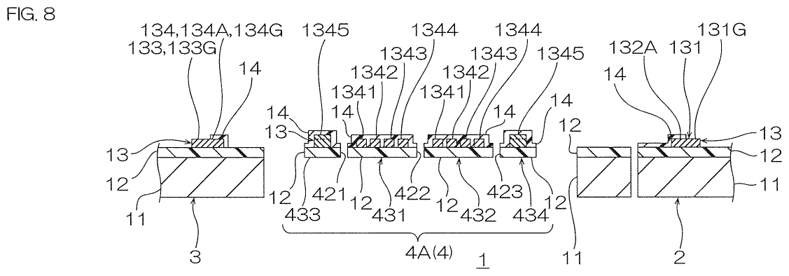

As shown in FIG. 8, the second joint 5 includes the metal supporting layer 11 and the base insulating layer 12.

### 3.4 Fourth Modified Example

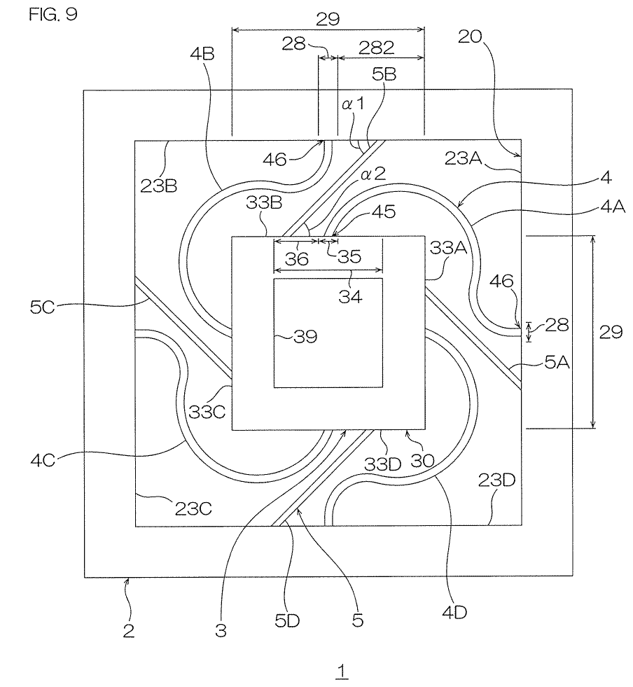

As shown in FIG. 9, the intermediate board 1 includes the four second joints 5A, 5B, 5C, and 5D. The second joint 5A connects the side 23A in the frame 2 to the side 33 A in the mounting portion 3. The second joint 5C connects the side 23C in the frame 2 to the side 33C in the mounting portion 3.

In the fourth modified example, the first joint 4 and the second joint 5 are disposed alternately in the direction along the periphery of the mounting portion 3. Specifically, in the direction along the periphery of the mounting portion 3, the second joint 5A, the first joint 4A, the second joint 5B, the first joint 4B, the second joint 5C, the first joint 4C, the second joint 5D, and the first joint 4D are disposed in order counterclockwise.

In the fourth modified example, as compared with one embodiment, since the number of second joints 5 is large, the intermediate board 1 in the second step has the excellent handleability.

In contrast, in one embodiment, as compared with the fourth modified example, since the number of second joints 5 is small, it is possible to easily remove the second joint 5 in the third step.

### 3.5 Fifth Modified Example

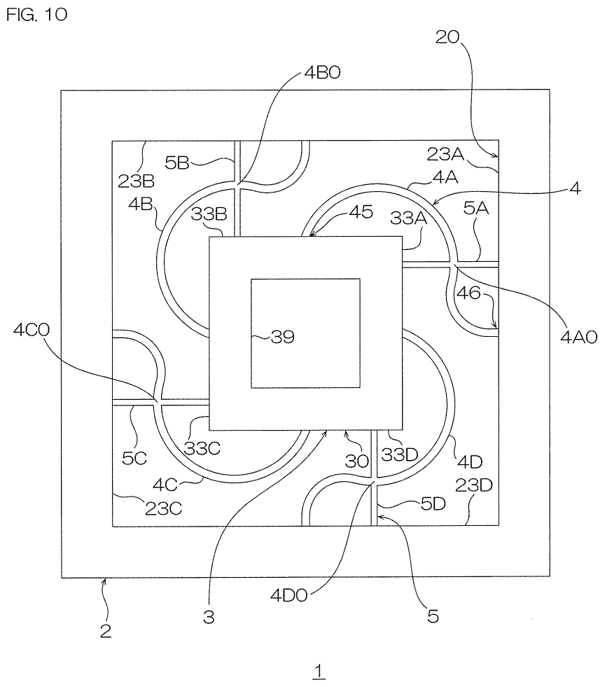

As shown in FIG. 10, the second joint 5 is partially overlapped with the first joint 4 in the thickness direction. In the fifth modified example, the second joint 5 intersects the first joint 4 in the thickness direction.

The second joint 5A has an intersection portion 4A0. In the intersection portion 4A0, the second joint 5A intersects the first joint 4A. The second joint 5B has an intersection portion 4B0. In the intersection portion 4B0, the second joint 5B intersects the first joint 4B. The second joint 5C has an intersection portion 4C0. In the intersection portion 4C0, the second joint 5C intersects the first joint 4C. The second joint 5D has an intersection portion 4D0. In the intersection portion 4D0, the second joint 5D intersects the first joint 4D.

In the fifth modified example, the second joint 5A is, for example, orthogonal to the side 23A and/or the side 33A.

### 3.6 Sixth Modified Example

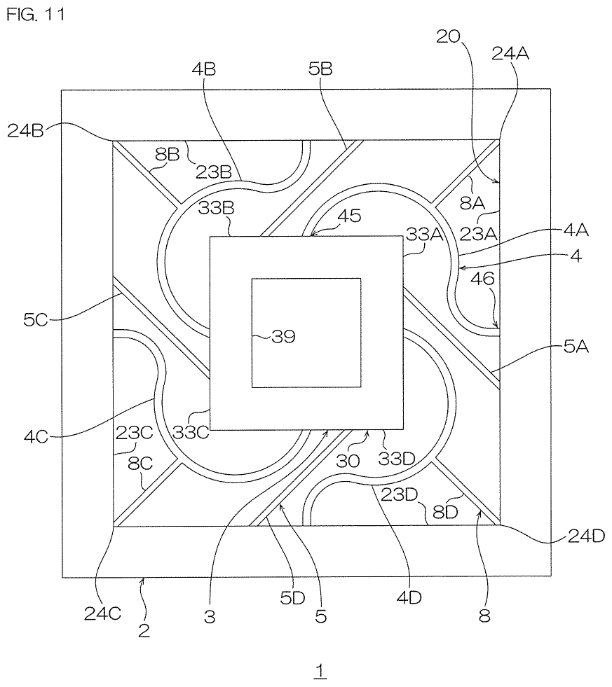

As shown in FIG. 11, the intermediate board 1 further includes a third joint 8.

### 3.6.1 First Step of Sixth Modified Example

In the first step, the intermediate board 1 further including the third joint 8 is prepared. The intermediate board 1 of the sixth modified example has the configuration in which the intermediate board 1 of the fourth modified example shown in FIG. 9 further includes the third joint 8.

The intermediate board 1 includes a plurality of third joints 8A, 8B, 8C, and 8D. The detailed descriptions of the third joint 8A are provided. The descriptions of the third joints 8B, 8C, and 8D are omitted.

The third joint 8A connects the frame 2 to the first joint 4. The third joint 8A is connected to a corner 24A in the frame 2. The corner 24A is formed by the side 23A and the side 23B adjacent to each other at the inner peripheral edge 20 of the frame 2.

The third joint 8A is connected to the intermediate portion of the first joint 4A in the direction in which the first joint 4A extends. The third joint 8 extends from the corner 24A of the frame 2 to the intermediate portion of the first joint 4A. However, the third joint 8 does not reach the mounting portion 3. The third joint 8A is inclined with respect to the side 23A.

### 3.6.2 Third Step of Sixth Modified Example

In the third step of the sixth modified example, the third joint 8 is removed together with the second joint 5. Therefore, the product board 100 does not include the second joint 5 and the third joint 8 (ref. FIG. 11).

### 3.6.3 Function and Effect of Sixth Modified Example

As shown in FIG. 11, in this production method, in the first step, since the intermediate board 1 including the third joint 8 supporting the first joint 4 is prepared, it is possible to increase the rigidity of the first joint 4 in the second step.

In this production method, in the third step, since the third joint 8 is removed, the mounting portion 3 is supported by the first joint 4. Therefore, it is possible to reliably correct the swing of the mounting portion 3.

### 3.7 Seventh Modified Example

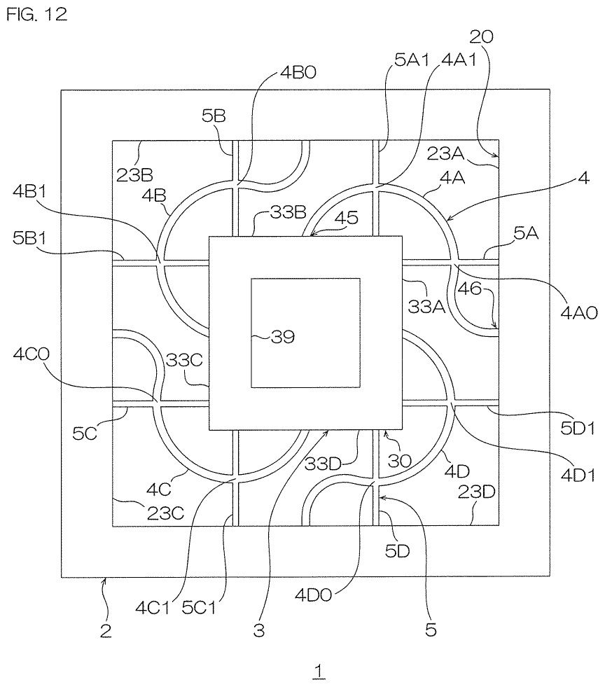

As shown in FIG. 12, in the seventh modified example, the two second joints 5A and 5A1 are provided corresponding to the one first joint 4A. The intermediate board 1 of the seventh modified example includes eight second joints 5A, 5A1, 5B, 5B1, 5C, 5C1, 5D, and 5D1.

The intermediate board 1 of the seventh modified example further includes the second joints 5A1, 5B1, 5C1, and 5D1 in addition to the second joints 5A, 5B, 5C, and 5D in the intermediate board 1 of the fifth modified example shown in FIG. 10.

The second joint 5A1 connects the side 23B in the frame 2 to the side 33B in the mounting portion 3. The second joint 5A1 intersects the first joint 4A in the thickness direction.

The second joint 5A1 has an intersection portion 4A1 in addition to the intersection portion 4A0. In the intersection portion 4A1, the second joint 5A1 intersects the first joint 4A. The intersection portion 4A1 and the intersection portion 4A0 are spaced apart from each other in the direction in which the first joint 4A extends. The second joint 5B1 has an intersection portion 4B1 in addition to the intersection portion 4B0. In the intersection portion 4B1, the second joint 5B1 intersects the first joint 4B. The intersection portion 4B1 and the intersection portion 4B0 are spaced apart from each other in the direction in which the first joint 4B extends. The second joint 5C1 has an intersection portion 4C1 in addition to the intersection portion 4C0. In the intersection portion 4C1, the second joint 5C1 intersects the first joint 4C. The intersection portion 4C1 and the intersection portion 4C0 are spaced apart from each other in the direction in which the first joint 4C extends. The second joint 5D1 has an intersection portion 4D1 in addition to the intersection portion 4D0. In the intersection portion 4D1, the second joint 5D1 intersects the first joint 4D. The intersection portion 4D1 and the intersection portion 4D0 are spaced apart from each other in the direction in which the first joint 4D extends.

### 3.8 Eighth Modified Example

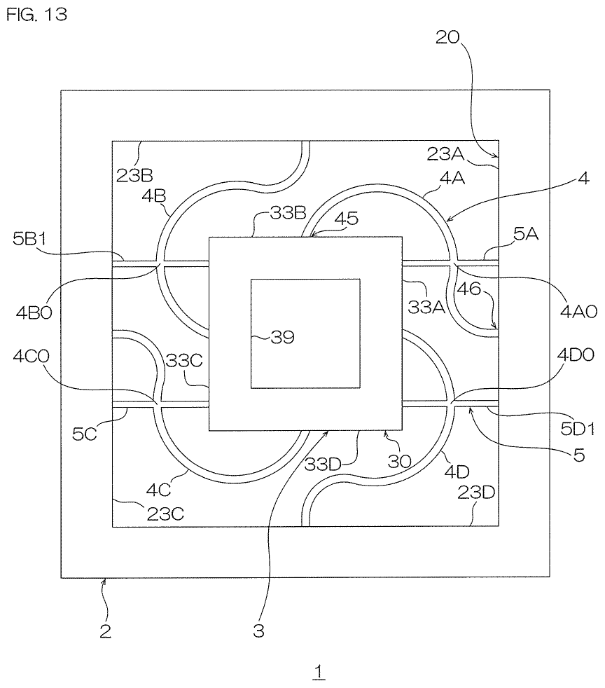

As shown in FIG. 13, the intermediate board 1 of the eighth modified example includes four second joints 5A, 5B1, 5C, and 5D1. Specifically, the intermediate board 1 of the eighth modified example does not include the four second joints 5A1, 5B, 5C1, and 5D (ref: FIG. 12) of the eight second joints 5A, 5A1, 5B, 5B1, 5C, 5C1, 5D, and 5D1 in the intermediate board 1 shown in FIG. 12.

### 3.9 Ninth Modified Example

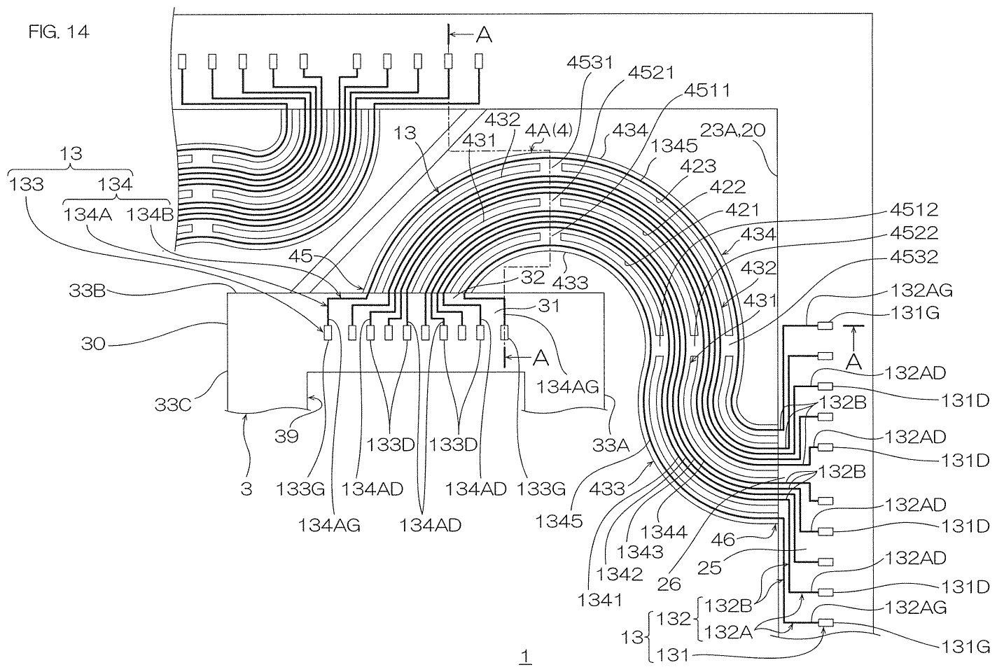

In the intermediate board 1, as shown in FIG. 14, each of the first joints 4A, 4B, 4C, and 4D includes sub-joints 4511, 4512, 4521, 4522, 4531, and 4532.

The sub-joints 4511 and 4512 divide the slit 421 in the direction in which the slit 421 extends. The sub-joints 4511 and 4512 are spaced apart from each other in the direction in which the slit 421 extends.

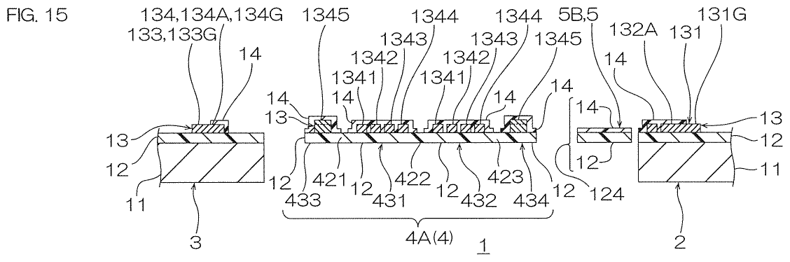

The sub-joints 4521 and 4522 divide the slit 422 in the direction in which the slit 422 extends. The sub-joints 4521 and 4522 are spaced apart from each other in the direction in which the slit 422 extends. As shown in FIG. 15, each of the sub-joints 4521 and 4522 connects the wiring body portion 431 to the wiring body portion 432. Further, each of the sub-joints 4521 and 4522 connects the joint wiring 1344 of the wiring body portion 431 to the joint wiring 1341 of the wiring body portion 432.

As shown in FIG. 14, the sub-joints 4511, 4521, and 4531 are disposed in alignment in the direction intersecting the direction in which the first joint 4 extends (intersecting direction, preferably, orthogonal direction). The sub-joints 4512, 4522, and 4532 are disposed in alignment in the direction intersecting the direction in which the first joint 4 extends (intersecting direction, preferably, orthogonal direction).

The sub-joints 4531 and 4532 divide the slit 423 in the direction in which the slit 421 extends. The sub-joints 4531 and 4532 are spaced apart from each other in the direction in which the slit 423 extends.

As shown in FIG. 15, the sub-joints 4511, 4512, 4521, 4522, 4531, and 4532 include the base insulating layer 12. In this modified example, the sub-joints 4511, 4512, 4521, 4522, 4531, and 4532 include only the base insulating layer 12.

According to the fourth modified example, it is possible to suppress an excessive reduction of the rigidity of each of the first joints 4A, 4B, 4C, and 4D caused by the slit 422 by the sub-joints 4521 and 4522. Therefore, it is possible to suppress a deformation of each of the first joints 4A, 4B, 4C, and 4D. Therefore, in the second step, it is possible to stabilize the posture of the mounting portion 3. As a result, the intermediate board 1 in the second step has the excellent handleability.

### 3.10 Tenth Modified Example

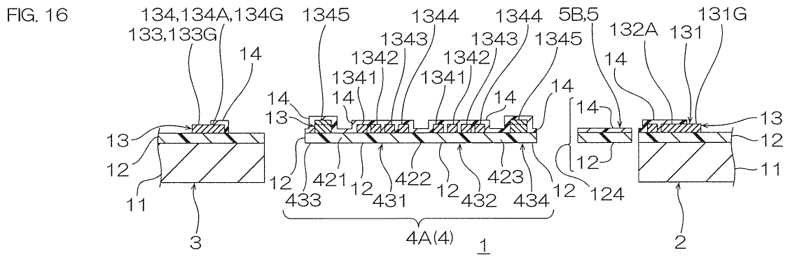

As shown in FIG. 16, the sub-joints 4511, 4512, 4521, 4522, 4531, and 4532 include the base insulating layer 12 and the cover insulating layer 14. In this modified example, the sub-joints 4511, 4512, 4521, 4522, 4531, and 4532 include only the base insulating layer 12 and the cover insulating layer 14.

Although not shown, the sub-joints 4511, 4512, 4521, 4522, 4531, and 4532 may also include only the cover insulating layer 14.

### 3.11 Eleventh Modified Example

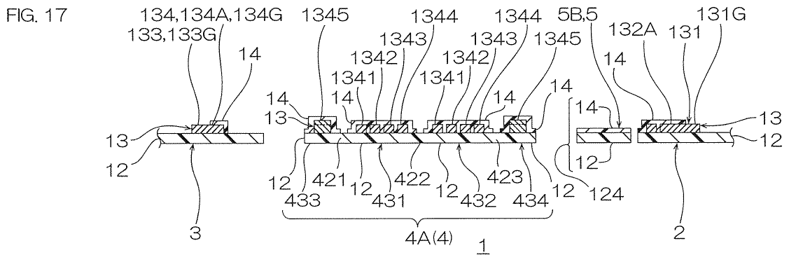

As shown in FIG. 17, each of the frame 2, the mounting portion 3, and the first joint 4 in the intermediate board 1 does not include the metal supporting layer 11.

### 3.12 Twelfth Modified Example and Thirteenth Modified Example

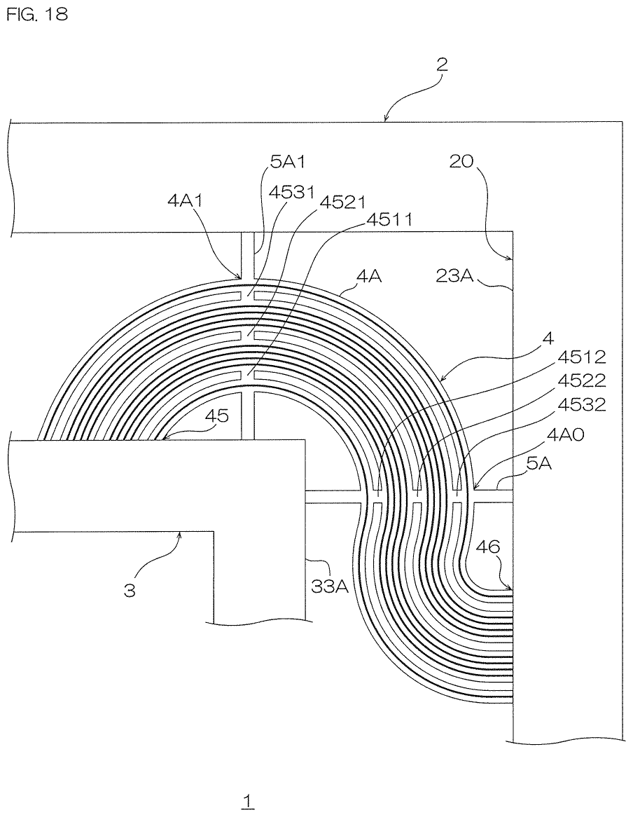

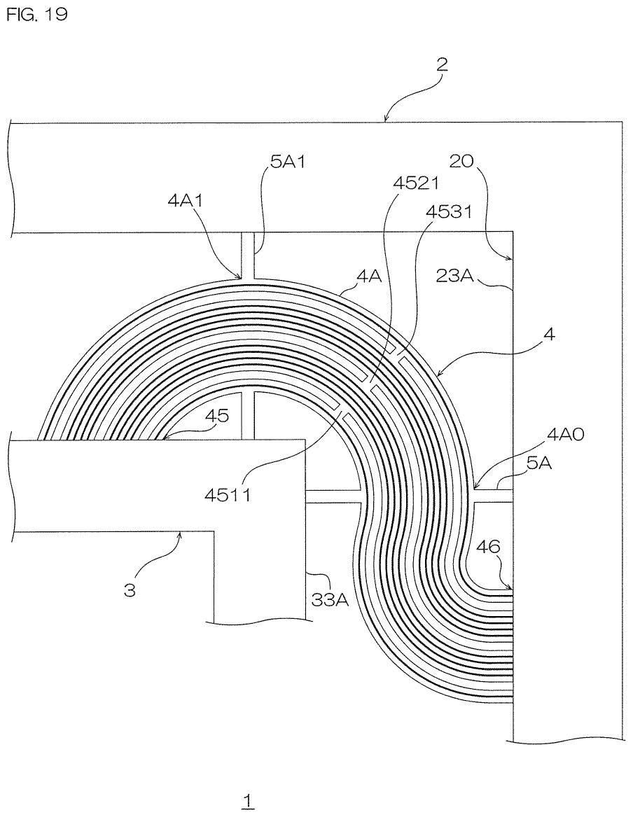

As shown in FIGS. 18 and 19, each of the twelfth modified example and the thirteenth modified example has the configuration in which the seventh modified example and the ninth modified example are used in combination. The two second joints 5A and 5A1 are provided corresponding to the one first joint 4A. Each of the first joints 4A, 4B, 4C, and 4D includes the sub-joints 4511, 4512, 4521, 4522, 4531, and 4532.

As shown in FIG. 18, in the twelfth modified example, the sub-joints 4511, 4521, and 4531 are disposed in the intersection portion 4A1. The sub-joints 4512, 4522, and 4532 are disposed in the intersection portion 4A0.

As shown in FIG. 19, in the thirteenth modified example, the sub-joints 4511, 4521, and 4531 are disposed between the intersection portion 4A1 and the intersection portion 4A0.

### 3.13 Fourteenth Modified Example

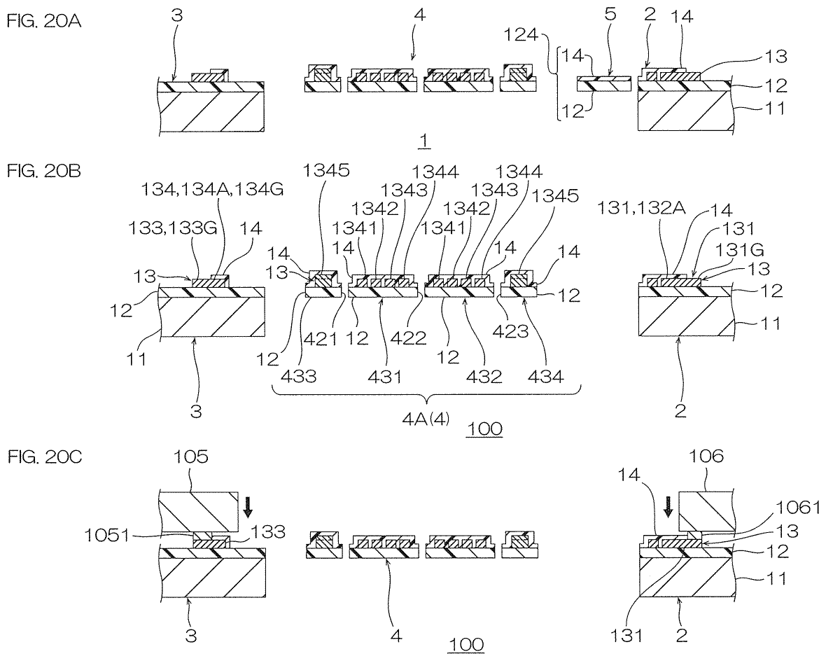

In the fourteenth modified example, as shown in FIG. 20B and FIG. 20C, the fourth step is carried out after the third step.

The method for producing the fourteenth modified example carries out the first step (ref: FIG. 20A), the second step, the third step (ref: FIG. 20B), and the fourth step (ref: FIG. 20C) in order.

As shown in FIG. 20B, in the third step, the second joint 5 in the intermediate board 1 (ref: FIG. 20A) is removed. Thus, the product board 100 is produced. The product board 100 is not yet mounted with the imaging element 105 (ref: FIG. 20C) and the external board 106 (ref: FIG. 20C).

As shown in FIG. 20C, in the fourth step, the imaging element 105 and the external board 106 are mounted on the product board 100. Specifically, the imaging element 105 is mounted on the mounting portion 3, and the external board 106 is mounted on the frame 2.

When one embodiment and the fourteenth modified example are compared, one embodiment is preferably used. In one embodiment, as shown in FIG. 4B, when the imaging element 105 in the fourth step is mounted on the mounting portion 3, since the mounting portion 3 is supported by the frame 2 via the second joint 5 in addition to the first joint 4, it is possible to further more stabilize the posture of the mounting portion 3. Therefore, in the fourth step, it is possible to reliably mount the imaging element 105 on the mounting portion 3.

### 3.14 Another Modified Example

In one embodiment, the second joint 5B includes the base insulating layer 12 and the cover insulating layer 14. Alternatively, though not shown, the second joint 5B may also include only the base insulating layer 12 or only the cover insulating layer 14.

In one embodiment, the first joint 4A does not include the metal supporting layer 11. Alternatively, in the modified example, the first joint 4 may also include the metal supporting layer 11.

In one embodiment, the mounting portion 3 has the rectangular frame shape. Alternatively, the mounting portion 3 may also have the rectangular shape without the inner peripheral edge 39 (ref: FIG. 1).

The mounting portion 3 may also have the curved shape, and further, may also have the circular shape. In this case, the outer peripheral edge 30 of the mounting portion 3 does not have the side.

The frame 2 may also have the curved shape, and further, may also have an annular shape. In this case, the inner peripheral edge 20 of the frame 2 does not have the side.

The second joint 5 may also have the curved shape and/or the bent shape. Examples of the curved shape include generally wavy shapes, S-shapes, and hooked shapes.

It is also possible to carry out the fourth step after the first step and before the second step.

In this modified example, the imaging element 105 is mounted on the mounting portion 3 in the fourth step, and thereafter, in the second step, it is possible to inspect the intermediate board 1 together with the imaging element 105.

In the above-described modified example, when the intermediate board 1 mounted with the imaging element 105 is defective, the imaging element 105 is discarded together with the intermediate board 1.

In contrast, in one embodiment, the fourth step is carried out before the second step. Specifically, in the second step, in a case where the intermediate board 1 is defective by inspecting the intermediate board 1, even when the intermediate board 1 is discarded, in the fourth step, it is possible to separately mount the imaging element 105 on another good intermediate board 1. That is, it is possible to prevent the above-described disposal of the imaging element 105. As described above, of one embodiment and the above-described modified examples, one embodiment is preferably used.

The number of second joints 5 may be also 1 or 3.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### Industrial Application

The wiring circuit board of the present invention is mounted with an imaging element. The wiring circuit board is provided in an imaging device.

### DESCRIPTION OF REFERENCE NUMERALS

1 Intermediate board (one example of wiring circuit board)
2 Frame
3 Mounting portion
4, 4A, 4B, 4C, 4D First joint
5, 5A, 5A1, 5B, 5B1, 5C, 5C1, 5D, 5D1 Second joint
8, 8A, 8B, 8C, 8D Third joint
11 Metal supporting layer
12 Base insulating layer (insulating layer)
13 Wiring layer
14 Cover insulating layer (insulating layer)
15 Third joint
23A, 23B, 23C, 23D Side
30 Outer peripheral edge
33A, 33B, 33C, 33D Side
100 Product board (one example of wiring circuit board)
105 Imaging element
134 Wiring
421, 422, 423 Slit
4511, 4512, 4521, 4522, 4531, 4532 Sub-joint
1341, 1342, 1343, 1344 Joint wiring

1. A method for producing a wiring circuit board comprising:
a first step of preparing a wiring circuit board including a frame, a mounting portion surrounded by the frame and spaced apart from the frame, and a first joint and a second joint connecting the frame to the mounting portion, and the wiring circuit board having each of the frame, the mounting portion, and the first joint including an insulating layer and a wiring layer disposed on one surface of the insulating layer in a thickness direction;
a second step of inspecting the wiring circuit board; and
a third step of removing the second joint in order.

2. The method for producing a wiring circuit board according to claim 1, wherein
the mounting portion has a generally rectangular shape, and has a side at an outer peripheral edge of the mounting portion;
the frame has a generally rectangular frame shape, and has a facing side facing the side and a non-facing side adjacent to the facing side and not facing the side;
the first joint connects the side to the non-facing side; and
the second joint connects the side to the facing side.

3. The method for producing a wiring circuit board according to claim 2, wherein
the side includes a first side and a second side along the first side;
at least each of the two first joints and the second joints is provided in the wiring circuit board in the first step;
each of the two first joints is connected to each of the first side and the second side; and
each of the two second joints is connected to each of the first side and the second side.

4. The method for producing a wiring circuit board according to claim 1, wherein
in the first step, the wiring circuit board further including a third joint connecting the frame to the first joint is prepared, and
in the third step, the third joint is further removed.

5. The method for producing a wiring circuit board according to claim 1, wherein
the second joint includes the insulating layer.

6. The method for producing a wiring circuit board according to claim 5, wherein
the insulating layer in the second joint includes a base insulating layer and/or a cover insulating layer.

7. The method for producing a wiring circuit board according to claim 6, wherein the second joint further includes the wiring layer.

8. The method for producing a wiring circuit board according to claim 1, wherein
each of the frame and the mounting portion further includes a metal supporting layer disposed on the other surface of the insulating layer in the thickness direction.

9. The method for producing a wiring circuit board according to claim 8, wherein
the second joint includes the metal supporting layer.

10. The method for producing a wiring circuit board according to claim 1, wherein
the wiring layer in the first joint has a plurality of joint wirings spaced apart from each other, and
the insulating layer in the first joint has a slit disposed between the plurality of joint wirings.

11. The method for producing a wiring circuit board according to claim 10, wherein
the slit extends along the plurality of joint wirings, and
the first joint has a sub-joint dividing the slit in a direction in which the slit extends, and connecting the plurality of joint wirings.

12. The method for producing a wiring circuit board according to claim 1, wherein
the second joint is not overlapped with the first joint in a thickness direction.

13. The method for producing a wiring circuit board according to claim 1, wherein
the second joint intersects the first joint.

14. The method for producing a wiring circuit board according to claim 1 further comprising:
a fourth step of mounting an imaging element on the mounting portion after the first step and before the third step.

15. The method for producing a wiring circuit board according to claim 14, wherein
the fourth step is carried out after the second step.

16. A wiring circuit board comprising:
a frame, a mounting portion surrounded by the frame and spaced apart from the frame, and a first joint and a second joint connecting the frame to the mounting portion, wherein
the mounting portion has a generally rectangular shape, and has a side at an outer peripheral edge of the mounting portion;
the frame has a generally rectangular frame shape, and has a facing side facing the side and a non-facing side adjacent to the facing side and not facing the side;
the first joint connects the side to the non-facing side; and
the second joint connects the side to the facing side.

17. The wiring circuit board according to claim 16, wherein
each of the mounting portion and the first joint includes an insulating layer and a wiring layer disposed on one surface of the insulating layer in a thickness direction, and
the second joint includes the insulating layer.

18. The wiring circuit board according to claim 17, wherein
the second joint further includes the wiring layer.

19. The wiring circuit board according to claim 17, wherein
each of the frame and the mounting portion further includes a metal supporting layer disposed on the other surface of the insulating layer in a thickness direction.

20. The wiring circuit board according to claim 17, wherein
the insulating layer in the second joint includes a base insulating layer and/or a cover insulating layer.

21. The wiring circuit board according to claim 17, wherein
the wiring layer in the first joint has a plurality of joint wirings spaced apart from each other, and
the insulating layer in the first joint has a slit disposed between the plurality of joint wirings.

22. The wiring circuit board according to claim 21, wherein
the slit extends along the plurality of joint wirings, and
the first joint has a sub-joint dividing the slit in a direction in which the slit extends, and connecting the plurality of joint wirings.

23. The wiring circuit board according to claim 16 further comprising:
a third joint connecting the frame to the first joint.
